(19) United States
(12) Patent Application Publication
(10) Pub. No.: US 2026/0236816 A1
(43) Pub. Date: Aug. 13, 2026

(54) Methods and Systems for Addressing Qubits in an Array for Quantum Computation

(71) Applicant: ATOM COMPUTING INC., Berkeley, CA (US)

(72) Inventors: Mickey MCDONALD, Longmont, CO (US); Matthew NORCIA, Boulder, CO (US)

(21) Appl. No.: 19/288,689

(22) Filed: Aug. 1, 2025

Related U.S. Application Data
(63) Continuation of application No. PCT/US2024/015613, filed on Feb. 13, 2024.
(60) Provisional application No. 63/484,951, filed on Feb. 14, 2023.

(51) Int. Cl. G06N 10/40

(52) U.S. Cl. CPC G06N 10/40

(57) ABSTRACT

Systems, methods, and computer-readable media of performing state detection of addressing qubits for non-classical computing, may include: (A) obtaining a plurality of qubits in an array of spatially distinct optical trapping sites; and (B) selectively exposing each qubit of a subset of said plurality of qubits to one or more light beams of a plurality of light beams, wherein: (i) each light beam of said plurality light beams comprises two gate operations that are the inverse of each other, and (ii) a target qubit in said subset of said plurality of qubits is exposed to each of said plurality of light beams that are collectively configured to selectively apply a rotation operation to said target qubit.

### CROSS-REFERENCE

This application is a continuation of PCT International Application No. PCT/US2024/015613, filed Feb. 13, 2024, which application claims the benefit of U.S. Provisional Application No. 63/484,951, filed Feb. 14, 2023, each of which are incorporated herein by reference in their entirety.

### STATEMENT AS TO FEDERALLY SPONSORED RESEARCH

This invention was made with the support of the United States Government under Grant Numbers 2040527 (Phase I) and 2134345 (Phase II) awarded by the National Science Foundation through the Convergence Accelerator Research Program. The United States Government has certain rights in this invention.

### BACKGROUND

Quantum computers typically make use of quantum-mechanical phenomena, such as superposition and entanglement, to perform operations on data. Quantum computers may be different from digital electronic computers based on transistors. For instance, whereas digital computers require data to be encoded into binary digits (bits), each of which is always in one of two definite states (0 or 1), quantum computation uses quantum bits (qubits), which can be in superpositions of states.

In neutral-atom quantum computers or simulation devices, qubits may be encoded in optically trapped atoms. The qubit can be represented by a linear superposition of its two orthonormal basis states. The two orthonormal basis states are usually denoted as

$$\vert 0 〉 = [ \begin{matrix}1 \\ 0\end{matrix} ] ( the “ zero state ” ) and \vert 1 〉 = [ \begin{matrix}0 \\ 1\end{matrix} ] ( the “ one state ” ) .$$

The two orthonormal basis states, {0 [symbol] , |1 [symbol] }, together called the computational basis, span the two-dimensional linear vector (Hilbert) space of the qubit. The basis states can also be combined to form product basis states, e.g., |00 [symbol] , |01 [symbol] , |10 [symbol] |11 [symbol] , each called a quantum register. Generally, n qubits are represented by a superposition state vector in 2 dimensional Hilbert space.

The ability to reliably detect the quantum state of a qubit may be important to the operation of a quantum computer. In architectures making use of trapped ions or neutral atoms, the state of the qubit is typically read out by collecting photons through imaging systems that spatially or temporally resolve the qubit states.

### SUMMARY

One aspect of the present disclosure provides a method of addressing qubits for non-classical computing, comprising: (a) obtaining a plurality of qubits in an array of spatially distinct optical trapping sites, wherein said plurality of qubits comprises a first subset of said plurality of qubits and a second subset of said plurality of qubits, and wherein said first subset of said plurality of qubits comprises a target qubit and said second subset of said plurality of qubits comprises said target qubit; and (b) exposing (i) said first subset of said plurality of qubits to a first light beam along a first axis and (ii) said second subset of said plurality of qubits to a second light beam along a second axis that is at an angle to said first axis, wherein said first light beam and said second light beam are configured to selectively apply a rotation operation to said target qubit and the identity operation to each of the other qubits in each of said first subset of said plurality of qubits and said second subset of said plurality of qubits. In some embodiments, the method further comprises: (c) exposing (i) a third subset of said plurality of qubits to a third light beam along a third axis that is parallel or skew to said first axis and (ii) a fourth subset of said plurality of qubits to a fourth light beam along a fourth axis that is parallel or skew to said second axis, wherein said third light beam and said fourth light beam are configured to selectively apply a second rotation operation to a second target qubit and the identity operation to each of the other qubits in each of said third subset of said plurality of qubits and said fourth subset of said plurality of qubits, wherein said third subset of said plurality of qubits comprises said second target qubit and said fourth subset of said plurality of qubits comprises said second target qubit. In some embodiments, a first grouping of qubits and a second grouping of qubits are, with exception for said target qubit and said second target qubit, mutually exclusive with respect to one another, and wherein: (i) said first grouping of qubits comprises said first subset of said plurality of qubits and said third subset of said plurality of qubits and (ii) said second grouping of qubits comprises said second subset of said plurality of qubits and said fourth subset of said plurality of qubits. In some embodiments, said rotation operation is the same as said second rotation operation. In some embodiments, said rotation operation is different than said second rotation operation. In some embodiments, said angle is about 90°, and wherein: (i) said first light beam applies operations of

$${R}_{x} ( \frac{θ}{2} ) and {R}_{x} ( - \frac{θ}{2} )$$

to said first subset of said plurality of qubits; and (ii) said second light beam applies operations of R_{y}(π) and R_{y}(−π) to said second subset of said plurality of qubits. In some embodiments, said rotation operation applied to said target qubit is a rotation of θ about the x-axis, wherein said first axis corresponds to the x-axis and said second axis corresponds to the y-axis. In some embodiments, (i) said first light beam applies operations of [A] and [A⁻¹] to said first subset of said plurality of qubits; and (ii) said second light beam applies operations of [B] and [B⁻¹] to said second subset of said plurality of qubits. In some embodiments, said rotation operation applied to said target qubit is a rotation of θ about the x-axis, wherein said first axis corresponds to the x-axis and said second axis corresponds to the y-axis. In some embodiments, said angle is less than 90° or more than 90°. In some embodiments, exposing said first subset of said plurality of qubits to said first light and said second subset of said plurality of qubits to said second light beam at (b) further comprises: (c) exposing a third subset of said plurality of qubits to a third light beam along a third axis, wherein: (i) said third subset of said plurality of qubits comprises said target qubit, (ii) said third light beam is configured to selectively apply a rotation operation to said target qubit and the identity operation to each of the other qubits in each of said first subset of said plurality of qubits and said second subset of said plurality of qubits, and (iii) each of said first subset of said plurality of qubits, said second subset of said plurality of qubits, and said third subset of said plurality of qubits are, with exception for said target qubit, mutually exclusive with respect to one another. In some embodiments, said target qubit is a single qubit. In some embodiments, said target qubit is a plurality of qubits. In some embodiments, said first light beam and said second light beam comprise a beam size configured to select a single target atom. In some embodiments, said first light beam and said second light beam comprise a beam size configured to select a plurality of target atoms. In some embodiments, said first light beam comprises a pair of optical pulses, and said second light beam comprises a second pair of optical pulses. In some embodiments, said first light beam is a first wavelength and said second light beam is a second wavelength, and wherein said first wavelength is about the same as said second wavelength. In some embodiments, said first wavelength and said second wavelength are between about 300 nanometers (nm) and 3000 nm. In some embodiments, said first light beam and said second light beam are each laser beams. In some embodiments, said first light beam and said second light beam each have a divergence angle less than 45 degrees. In some embodiments, said first light beam and said second light beam are each generated by a microscope objective with a numerical aperture of less than 0.7. In some embodiments, said first light beam comprises a first operation and a second operation and said second light beam comprises a third operation and a fourth operation. In some embodiments, said first operation is the inverse of said second operation and said third operation is the inverse of the fourth operation. In some embodiments, (b) comprises (i) exposing said first subset of said plurality of qubits to said first operation and exposing said second subset of said plurality of qubits to said second operation prior to (ii) exposing said first subset of said plurality of qubits to said third operation and exposing said second subset of said plurality of qubits to said fourth operation. In some embodiments, said plurality of qubits comprise neutral atoms. In some embodiments, said neutral atoms comprise a Group II element. In some embodiments, said Group II element is strontium. In some embodiments, said neutral atoms comprise ytterbium. In some embodiments, said qubits comprise a temperature of at most 10 microkelvin (μK). In some embodiments, the method further comprises performing a non-classical computation based at least in part on selectively applying said rotation operation to said target qubit at (b).

Another aspect of the present disclosure provides a system of addressing qubits for non-classical computing, comprising: (a) one or more optical trapping units configured to obtain an array of spatially distinct optical trapping sites, wherein: (i) said array comprises a plurality of qubits, (ii) said plurality of qubits comprises a first subset of said plurality of qubits and a second subset of said plurality of qubits, and (iii) said first subset of said plurality of qubits comprises a target qubit and said second subset of said plurality of qubits comprises said target qubit; and (b) one or more light sources configured to expose: (i) said first subset of said plurality of qubits to a first light beam along a first axis, and (ii) said second subset of said plurality of qubits to a second light beam along a second axis that is orthogonal to said first axis, wherein said first light beam and said second light beam are configured to selectively apply a rotation operation to said target qubit and the identity operation to each of the other qubits in each of said first subset of said plurality of qubits and said second subset of said plurality of qubits. The system of claim 31, further comprising one or more electromagnetic delivery units, wherein said one or more electromagnetic delivery units comprise said one or more light sources.

Another aspect of the present disclosure provides a non-transitory computer-readable media comprising machine-executable code comprising one or more instructions that, upon execution, implement a method of addressing qubits for non-classical computing on a non-classical computer, wherein said non-classical computer is configured to execute said one or more instructions, the method comprising: (a) obtaining a plurality of qubits in an array of spatially distinct optical trapping sites, wherein said plurality of qubits comprises a first subset of said plurality of qubits and a second subset of said plurality of qubits, and wherein said first subset of said plurality of qubits comprises a target qubit and said second subset of said plurality of qubits comprises said target qubit; and (b) exposing (i) said first subset of said plurality of qubits to a first light beam along a first axis and (ii) said second subset of said plurality of qubits to a second light beam along a second axis that is at an angle to said first axis, wherein said first light beam and said second light beam are configured to selectively apply a rotation operation to said target qubit and the identity operation to each of the other qubits in each of said first subset of said plurality of qubits and said second subset of said plurality of qubits.

Another aspect of the present disclosure provides a method of addressing qubits for non-classical computing, comprising: (a) obtaining a plurality of qubits in an array of spatially distinct optical trapping sites; and (b) selectively exposing each qubit of a subset of said plurality of qubits to one or more light beams of a plurality of light beams, wherein: (i) each light beam of said plurality light beams comprises two gate operations that are the inverse of each other, and (ii) a target qubit in said subset of said plurality of qubits is exposed to each of said plurality of light beams that are collectively configured to selectively apply a rotation operation to said target qubit. In some embodiments, one or more qubits of said subset of qubits that are not said target qubit are each exposed to a subset of said plurality of light beams, wherein operations produced by said subset of said plurality of light beams substantially commute. In some embodiments, (i) a first light beam of said plurality of light beams applies operations of [A] and [A⁻¹] to said target qubit; and (ii) a second light beam of said plurality of light beams applies operations of [B] and [B⁻¹] to said target qubit. In some embodiments, a third light beam of said plurality of light beams applies operations of [C] and [C⁻¹] to said target qubit. In some embodiments, (b) comprises (i) applying said operation of [A] and said operation of [B] to said target qubit prior to (ii) applying said operation of [A⁻¹] and said operation of [B⁻¹] to said target qubit. In some embodiments, said target qubit is a single qubit. In some embodiments, said target qubit is a plurality of qubits. In some embodiments, at least one of said plurality of light beams is a planar light beam. In some embodiments, at least one of said plurality of light beams is a light beam with a focus elongated in at least one direction. In some embodiments, said plurality of light beams comprises at least 3 light beams. In some embodiments, said plurality of light beams comprises at least 4 light beams. In some embodiments, said plurality of light beams comprises at least 5 light beams. In some embodiments, said plurality of light beams comprises at least 10 light beams. In some embodiments, said subset of said plurality of qubits comprises at least two qubits.

Another aspect of the present disclosure provides a system of addressing qubits for non-classical computing, comprising: (a) one or more optical trapping units configured to obtain an array of spatially distinct optical trapping sites; and (b) one or more electromagnetic delivery units configured to selectively expose a subset of said plurality of qubits to one or more light beams of a plurality of light beams, wherein: (i) each light beam of said plurality light beams comprises two gate operations that are the inverse of each other, and (ii) a target qubit in said subset of said plurality of qubits is exposed to each of said plurality of light beams that are collectively configured to selectively apply a rotation operation to said target qubit.

Another aspect of the present disclosure provides a non-transitory computer-readable media comprising machine-executable code comprising one or more instructions that, upon execution, implement a method of addressing qubits for non-classical computing on a non-classical computer, wherein said non-classical computer is configured to execute said one or more instructions, the method comprising: (a) obtaining a plurality of qubits in an array of spatially distinct optical trapping sites; and (b) selectively exposing each qubit of a subset of said plurality of qubits to one or more light beams of a plurality of light beams, wherein: (i) each light beam of said plurality light beams comprises two gate operations that are the inverse of each other, and (ii) a target qubit in said subset of said plurality of qubits is exposed to each of said plurality of light beams that are collectively configured to selectively apply a rotation operation to said target qubit.

Another aspect of the present disclosure provides a method of addressing qubits for non-classical computing, including: (A) obtaining a plurality of qubits in a three-dimensional array of spatially distinct optical trapping sites, wherein said plurality of qubits comprises a first subset of said plurality of qubits and a second subset of said plurality of qubits, and wherein a target qubit is included in both said first subset of said plurality of qubits and said second subset of said plurality of qubits; and (B) exposing (i) said first subset of said plurality of qubits to a first light beam along a first axis and (ii) said second subset of said plurality of qubits to a second light beam along a second axis that is orthogonal to said first axis, thereby applying a rotation operation to said target qubit and the identity operation to each of the other qubits in each of said first subset of said plurality of qubits and said second subset of said plurality of qubits.

Another aspect of the present disclosure provides a system of addressing qubits for non-classical computing, including: (A) one or more optical trapping units configured to obtain a three-dimensional array of spatially distinct optical trapping sites, wherein: said three-dimensional array comprises a plurality of qubits, said plurality of qubits comprises a first subset of said plurality of qubits and a second subset of said plurality of qubits, and a target qubit is included in both said first subset of said plurality of qubits and said second subset of said plurality of qubits; and (B) one or more light sources configured to expose (i) said first subset of said plurality of qubits to a first light beam along a first axis and (ii) said second subset of said plurality of qubits to a second light beam along a second axis that is orthogonal to said first axis, thereby applying a rotation operation to said target qubit and the identity operation to each of the other qubits in each of said first subset of said plurality of qubits and said second subset of said plurality of qubits.

Another aspect of the present disclosure provides a non-transitory computer-readable media comprising machine-executable code comprising one or more instructions that, upon execution, implement a method of addressing qubits for non-classical computing on a non-classical computer, wherein said non-classical computer is configured to execute said one or more instructions, the method comprising: (A) obtaining a plurality of qubits in a three-dimensional array of spatially distinct optical trapping sites, wherein said plurality of qubits comprises a first subset of said plurality of qubits and a second subset of said plurality of qubits, and wherein a target qubit is included in both said first subset of said plurality of qubits and said second subset of said plurality of qubits; and (B) exposing (i) said first subset of said plurality of qubits to a first light beam along a first axis and (ii) said second subset of said plurality of qubits to a second light beam along a second axis that is orthogonal to said first axis, thereby applying a rotation operation to said target qubit and the identity operation to each of the other qubits in each of said first subset of said plurality of qubits and said second subset of said plurality of qubits.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 shows a computer control system that is programmed or otherwise configured to implement methods provided herein;

FIG. 2 shows an example of a system for performing a non-classical computation;

FIG. 3A shows an example of an optical trapping unit;

FIG. 3B shows an example of a plurality of optical trapping sites;

FIG. 3C shows an example of an optical trapping unit that is partially filled with atoms;

FIG. 3D shows an example of an optical trapping unit that is completely filled with atoms;

FIG. 4 shows an example of an electromagnetic delivery unit;

FIG. 5 shows an example of a state preparation unit;

FIG. 6 shows a flowchart for an example of a first method for performing a non-classical computation;

FIG. 7 shows a flowchart for an example of a second method for performing a non-classical computation;

FIG. 8 shows a flowchart for an example of a third method for performing a non-classical computation;

FIG. 9 shows an energy level structure for single-qubit and multi-qubit operations in strontium-87;

FIG. 10 illustrates an example diagram of two light beams addressing a target qubit;

FIG. 11A illustrates a first perspective of an example diagram of a plurality of parallel pairs of light beams addressing target qubits;

FIG. 11B illustrates a second perspective of an example diagram of a plurality of parallel pairs of light beams addressing target qubits;

FIG. 12 illustrates an example diagram of three light beams addressing a target qubit;

FIG. 13 illustrates an example diagram of two non-orthogonal light beams addressing a target qubit;

FIG. 14A illustrates a first perspective of an example diagram of two light beams with foci elongated along a single direction addressing a line of target qubits;

FIG. 14B illustrates a second perspective of an example diagram of two light beams with foci elongated along a single direction addressing a line of target qubits;

FIG. 15 illustrates an example diagram of four light beams and a planar light beam addressing four target qubits; and

FIG. 16 illustrates an example method of performing state detection of addressing qubits for non-classical computing.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

This disclosure hereby incorporates by reference for all purposes, (A) K. Barnes et al., “Assembly and coherent control of a register of nuclear spin qubits”. Nature Communications, 13(1) (2022); (B) D. McKay et al., “Efficient Z gates for quantum computing”. Physical Review A 96.2 (2017); (C) Y. Wang et al. “Universal gates based on targeted phase shifts in a 3D neutral atom array”. arXiv preprint arXiv:1601.03639 (2016); and (D) Team, T. Q. “More circuit identities”. qiskit.org. (https: qiskit.org textbook ch-gates more-circuit-identities.html)(2022).

There are numerous challenges in addressing a single qubit (e.g., atoms, ions, etc.) in an array without perturbing the neighbors of the single qubit. For 1-dimensional and 2-dimensional arrays of qubits, a technique of shining a tightly-focused laser beam at a single qubit, such that the light falls on the single qubit without overlapping its neighbors, can be accomplished by arranging neighboring qubits of the single qubit along a direction perpendicular to the propagation direction of the addressing laser beam. However, for 3-dimensional arrays of tightly-spaced qubits, this technique may be no longer possible as a laser focused onto a single qubit deep within the 3-dimensional array may also cast light onto neighboring qubits of the single qubit that fall along the laser's propagation direction.

Systems, methods, computer-readable media, and techniques described herein protect neighboring qubits of a single qubit from stray light of a laser focused on the single qubit deep within a 3-dimensional array. The systems, the methods, the computer-readable media, and the techniques described herein may achieve this result by providing an addressing scheme which can apply an arbitrary rotation about a particular axis of the Bloch sphere to any arbitrary qubit within an array without perturbing the quantum state of its neighbors. In some cases, the array is a 3-dimensional array. In some cases, the array is a 1-dimensional or a 2-dimensional array of qubits.

### Example Target Qubit Addressin in an Array

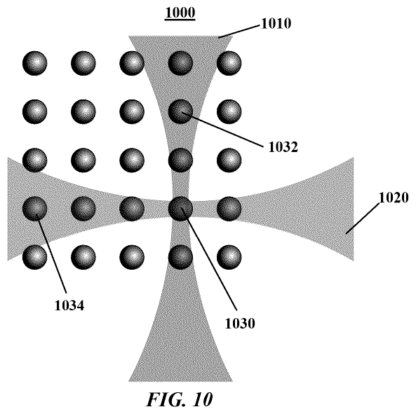

FIG. 10 illustrates an example of two light beams addressing a target qubit (e.g., a neutral atom, an ion, etc.) within a slice of a 3-dimensional array. As illustrated, an addressing scheme may apply an arbitrary rotation about a particular axis of the Bloch sphere to any arbitrary qubit within a 3-dimensional array without perturbing the quantum state of its neighbors. Operations described by Expression 1 may enable performing an arbitrary rotation by an angle θ about the x-axis of the Bloch sphere on a particular qubit.

$${R}_{x} ( \frac{θ}{2} ) * {R}_{y} ( π ) * {R}_{x} ( - \frac{θ}{2} ) * {R}_{y} ( - π ) , \qquad ( Expression 1 )$$

where the y-axis on the Bloch sphere is perpendicular to the x-axis. Operations of

$${R}_{x} ( \frac{θ}{2} ) and {R}_{x} ( - \frac{θ}{2} )$$

are applied by light traveling along axis “1” and operations of R_{y}(π) and R_{y}(−π) are applied by light traveling along axis “2”, such that axes “1” and “2” are perpendicular to one another. As illustrated, the axis “1” may be the x-axis and the axis “2” may be the y-axis. FIG. 10 provides a visual representation of the addressing beam geometry, with axis “1” corresponding to light beam 1010 (e.g., a laser beam), axis “2” corresponding to light beam 1020 (e.g., a laser beam), and the target qubit illustrated as target qubit 1030.

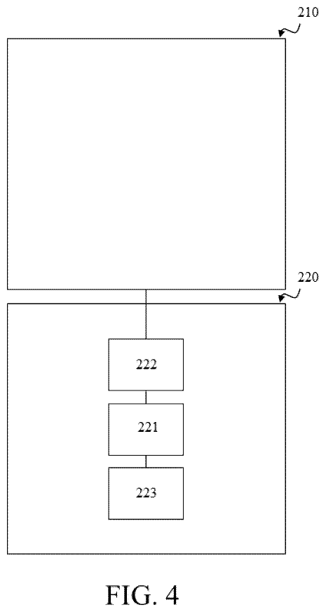

While “light beam(s)” are disclosed herein, it should be understood this is example language that may include one or more types of electromagnetic energies. The electromagnetic energy (e.g., light beam, laser, optical tweezer, etc.) may be delivered by one or more electromagnetic delivery units, such as disclosed herein with respect to FIG. 4. For example, light beams (e.g., the light beam 1010 and the light beam 1020) may be applied via the electromagnetic delivery unit 220, which may, in turn, include one or more of the light source 221, the OM 222, or the AI unit 223. In some cases, the light beam 1010 and the light beam 1020 may be the same or similar wavelengths. In some cases, the light beam 1010 and the light beam 1020 may be about the same wavelength (e.g., within about 1%, within about 5%, within about 10%, within about 20%, etc.). In some cases, the wavelength of the light beams 1010 and 1020 are different from each other. In some cases, the wavelength of one or both of the light beams 1010 or 1020 may be about 10 nanometers to about 1,000 nanometers. In some cases, the wavelength of one or both of the light beams 1010 or 1020 may be about 10 nanometers to about 100 nanometers, about 10 nanometers to about 150 nanometers, about 10 nanometers to about 200 nanometers, about 10 nanometers to about 300 nanometers, about 10 nanometers to about 400 nanometers, about 10 nanometers to about 500 nanometers, about 10 nanometers to about 600 nanometers, about 10 nanometers to about 700 nanometers, about 10 nanometers to about 800 nanometers, about 10 nanometers to about 900 nanometers, about 10 nanometers to about 1,000 nanometers, about 100 nanometers to about 150 nanometers, about 100 nanometers to about 200 nanometers, about 100 nanometers to about 300 nanometers, about 100 nanometers to about 400 nanometers, about 100 nanometers to about 500 nanometers, about 100 nanometers to about 600 nanometers, about 100 nanometers to about 700 nanometers, about 100 nanometers to about 800 nanometers, about 100 nanometers to about 900 nanometers, about 100 nanometers to about 1,000 nanometers, about 150 nanometers to about 200 nanometers, about 150 nanometers to about 300 nanometers, about 150 nanometers to about 400 nanometers, about 150 nanometers to about 500 nanometers, about 150 nanometers to about 600 nanometers, about 150 nanometers to about 700 nanometers, about 150 nanometers to about 800 nanometers, about 150 nanometers to about 900 nanometers, about 150 nanometers to about 1,000 nanometers, about 200 nanometers to about 300 nanometers, about 200 nanometers to about 400 nanometers, about 200 nanometers to about 500 nanometers, about 200 nanometers to about 600 nanometers, about 200 nanometers to about 700 nanometers, about 200 nanometers to about 800 nanometers, about 200 nanometers to about 900 nanometers, about 200 nanometers to about 1,000 nanometers, about 300 nanometers to about 400 nanometers, about 300 nanometers to about 500 nanometers, about 300 nanometers to about 600 nanometers, about 300 nanometers to about 700 nanometers, about 300 nanometers to about 800 nanometers, about 300 nanometers to about 900 nanometers, about 300 nanometers to about 1,000 nanometers, about 400 nanometers to about 500 nanometers, about 400 nanometers to about 600 nanometers, about 400 nanometers to about 700 nanometers, about 400 nanometers to about 800 nanometers, about 400 nanometers to about 900 nanometers, about 400 nanometers to about 1,000 nanometers, about 500 nanometers to about 600 nanometers, about 500 nanometers to about 700 nanometers, about 500 nanometers to about 800 nanometers, about 500 nanometers to about 900 nanometers, about 500 nanometers to about 1,000 nanometers, about 600 nanometers to about 700 nanometers, about 600 nanometers to about 800 nanometers, about 600 nanometers to about 900 nanometers, about 600 nanometers to about 1,000 nanometers, about 700 nanometers to about 800 nanometers, about 700 nanometers to about 900 nanometers, about 700 nanometers to about 1,000 nanometers, about 800 nanometers to about 900 nanometers, about 800 nanometers to about 1,000 nanometers, or about 900 nanometers to about 1,000 nanometers. In some cases, the wavelength of one or both of the light beams 210 or 220 may be about 10 nanometers, about 100 nanometers, about 150 nanometers, about 200 nanometers, about 300 nanometers, about 400 nanometers, about 500 nanometers, about 600 nanometers, about 700 nanometers, about 800 nanometers, about 900 nanometers, or about 1,000 nanometers. In some cases, the wavelength of one or both of the light beams 210 or 220 may be at least about 10 nanometers, about 100 nanometers, about 150 nanometers, about 200 nanometers, about 300 nanometers, about 400 nanometers, about 500 nanometers, about 600 nanometers, about 700 nanometers, about 800 nanometers, or about 900 nanometers. In some cases, the wavelength of one or both of the light beams 1010 or 1020 may be at most about 100 nanometers, about 150 nanometers, about 200 nanometers, about 300 nanometers, about 400 nanometers, about 500 nanometers, about 600 nanometers, about 700 nanometers, about 800 nanometers, about 900 nanometers, or about 1,000 nanometers.

In some cases, Equation 1 illustrates the net effect of the light beam 1010 and the light beam 1020 both addressing the target qubit 1030.

$${R}_{x} ( \frac{θ}{2} ) * {R}_{y} ( π ) * {R}_{x} ( - \frac{θ}{2} ) * {R}_{y} ( - π ) = {R}_{x} ( θ ) . \qquad ( Equation 1 )$$

Therefore, based on Equation 1, when the target qubit 1030 is addressed by the light beam 210 and the light beam 1020, the target qubit 1030 may rotate 0 degrees around the x-axis or axis “1.” This rotation about an axis in the Bloch sphere may function effectively as a 1-qubit gate operation.

Neighboring qubits hit by the light beam 1020 may be located away from the focal point of the light beam 1020, and therefore may see a smaller light intensity than is seen by the target qubit 230. Because of this, the neighboring qubits, such as qubit 1034, may undergo a smaller rotation about the x-axis, say by a factor of K. However, the neighboring qubits may not see any intensity from the light beam 1010. Therefore, the total effect on of the light beam 1010 and the light beam 1020 on the neighboring qubits, such as the qubit 1034, may be described according to Equation 2,

$${R}_{x} ( κ \frac{θ}{2} ) * {R}_{x} ( - κ \frac{θ}{2} ) = I , \qquad ( Equation 2 )$$

where I is the identity operation.

Similarly, neighboring qubits hit by the light beam 1010 may also be located away from the focal point of the light beam 1010, and therefore may see a smaller light intensity than is seen by the target qubit 1030. Because of this, the neighboring qubits, such as qubit 1032, may undergo a smaller rotation about the y-axis, which may be βπ. However, the neighboring qubits may not see any intensity from the light beam 1010. Therefore, the total effect on of the light beam 1010 and the light beam 1020 on the neighboring qubits, such as the qubit 1032, may be described according to Equation 3,

$${R}_{y} ( βπ ) * {R}_{y} ( - βπ ) = I , \qquad ( Equation 3 )$$

where I is the identity operation.

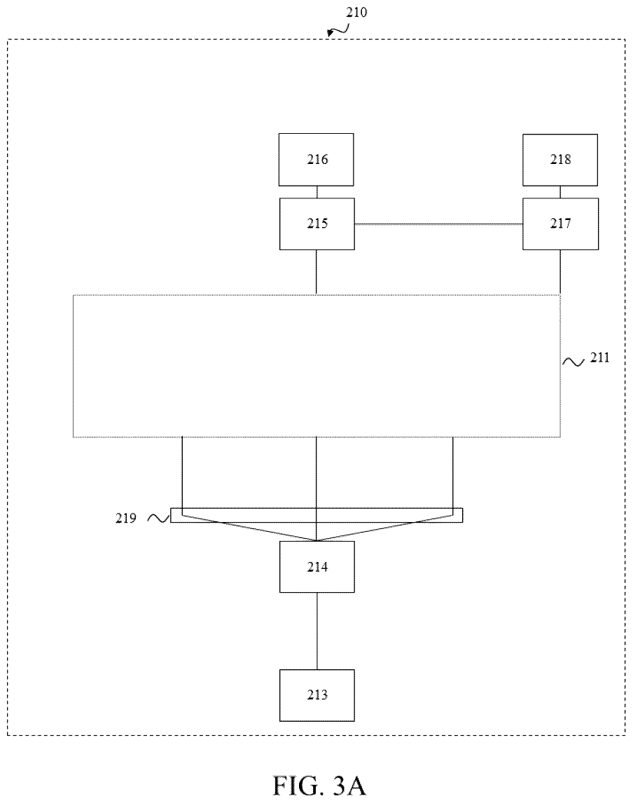

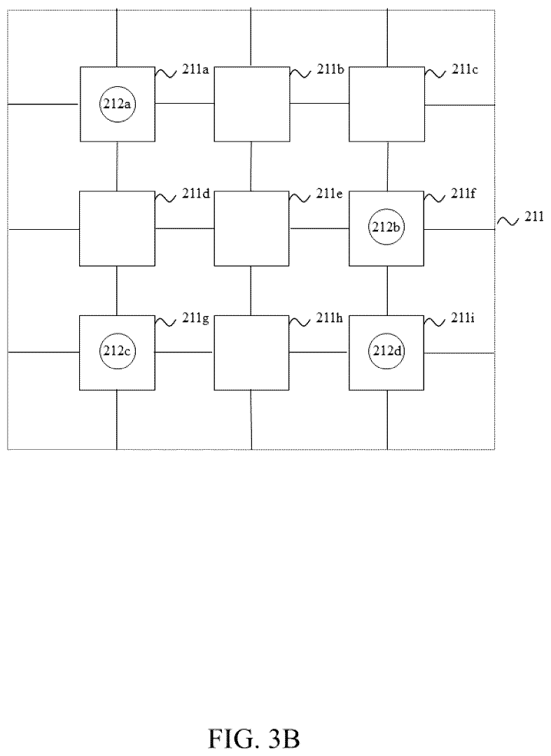

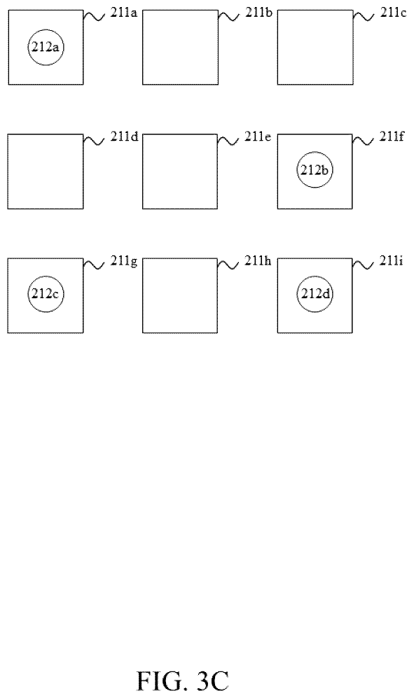

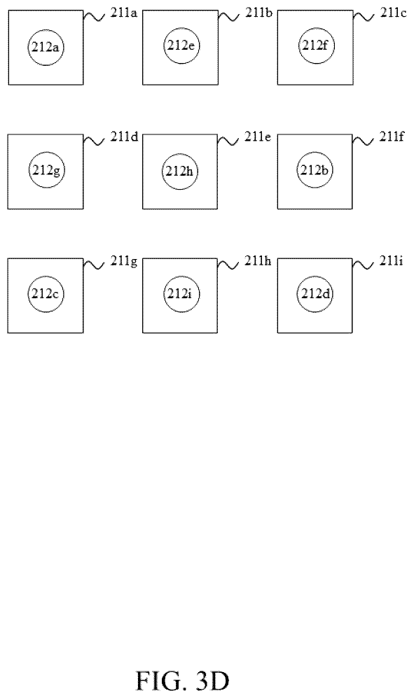

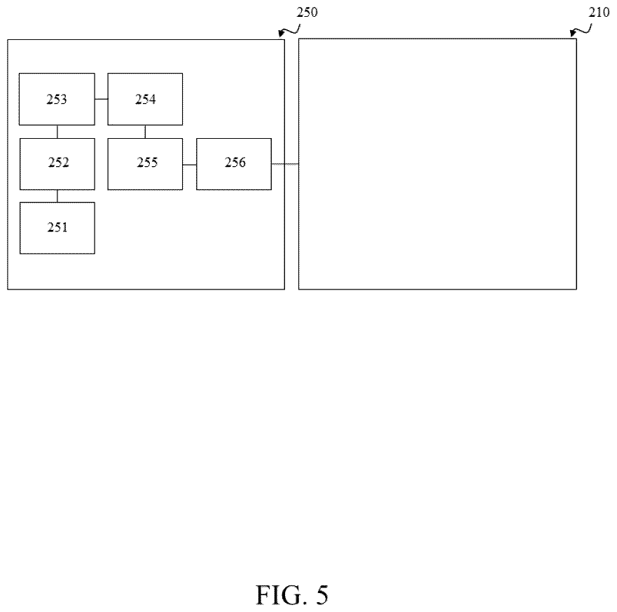

Therefore, as disclosed with respect to Equations 2 and 3, neighboring qubits that are exposed to a single light beam undergo the identity operation and are therefore not rotated. In other words, a neighboring qubit exposed to stray light from only a single direction may undergo identity operation because the net effect of the stray light may be to apply a complicated rotation about one axis, and then exactly “undo” that rotation on the subsequent pulse. Neighboring qubits undergo the identity operation because rotations about a single axis commute, while rotations about orthogonal axes do not. As the total effect of the light beam 1010 and the light beam 1020 on neighboring qubits (e.g., the qubit 1032 and 1034) is the identity operation, only the target qubit 1030 may rotate. The target qubit 1030 and the neighboring qubits (e.g., the qubit 1032 and 1034) may be positioned in an array (e.g., a one-dimensional array, a two-dimensional array, a three-dimensional array, etc.) by one or more optical trapping units, such as disclosed herein with respect to FIGS. 3A-3C. The target qubit 1030 and the neighboring qubits (e.g., the qubit 1032 and 1034) may be prepared by a state preparation unit (e.g., the state preparation unit 250 of FIG. 5) to configure the qubits for quantum computation

Although FIG. 10 illustrates the axes as the x-axis and y-axis, in some cases, the axes of incident light beams may be different axes. For example, by suitable application of virtual z-gates, the orientation of the x-axis may lie anywhere the xy-plane.

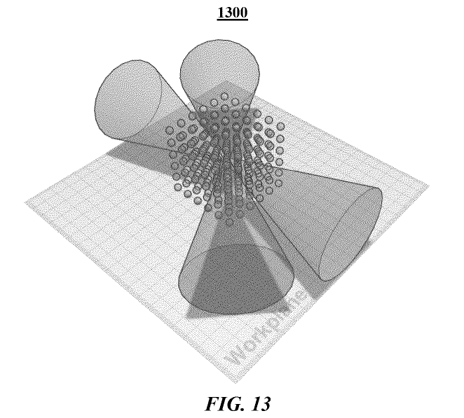

Although FIG. 10 illustrates the axes of light beams 1010 and 1020 as orthogonal, in some cases, the axes of incident light beams 1010 and 1020 are not orthogonal. FIG. 13 illustrates an example diagram 1300 of two non-orthogonal light beams addressing a target qubit. As illustrated, the light beams may intersect at an arbitrary angle.

Expression 1 and Equations 1-3 may be rewritten in a general form for an arbitrary angle. Equation 4 describes light beams of arbitrary angle with respect to one another, such that only the target qubit (or, in some cases, target qubits) in the array is illuminated by both light beams simultaneously,

$${U}_{target} = [ {A}^{- 1} ] [ {B}^{- 1} ] [ A ] [ B ] . \qquad ( Equation 4 )$$

In Equation 4, A and B are any arbitrary invertible operators, where “A” operations are sourced from a first light beam and “B” operations are sourced from a second light beam. For example, if A is the Rₓ(90°) gate and B is a R_{y}(180°), then U_{target} will be an Rₓ(180°) gate, and the identity operation will be applied to all other qubits that are not the target qubit. While the two light beams may intersect at an arbitrary angle, in some cases, the arbitrary angle may be at least the divergence angle of either light beam, otherwise there may be a line of qubits that sees intensity from both light beams.

Equation 4 also demonstrates how application of the A and B operators may be interspersed or interwoven such that both [A⁻¹] and [B⁻¹] are collectively applied prior to [A] and [B]. In some cases, [A⁻¹] is applied before [B⁻¹]. In some cases, [A⁻¹] is applied during at least part of the application of [B⁻¹]. In some cases, [A⁻¹] is applied substantially simultaneously with [B⁻¹]. In some cases, [A] is applied before [B]. In some cases, [B] is applied before [A]. In some cases, [A] is applied during at least part of the application of [B]. In some cases, [A] is applied substantially simultaneously with [B]. In a first example, the operators may be applied in the time-ordered steps of (1) [A⁻¹], (2) [B⁻¹], (3) [A], and (4) [B]. In a second example, the operators may be applied in the time-ordered steps of (1) [A⁻¹], (2) [B⁻¹], (3) [B], and (4) [A]. In some cases, in either the first example or the second example, step (1) may occur with at least some time overlap with step (2). In some cases, in either the first example or the second example, step (3) may occur with at least some time overlap with step (4). In some cases, in either the first example or the second example, step (2) may at least partially occur prior to step (3).

The diagram 1300 of FIG. 13 illustrates how the two intersecting light beams intersect at an angle less than 900 but greater than the divergence angle of either beam. In cases in which both light beams have a divergence angle of 45°, the light beams may intersect at 900 in order to ensure only a single target qubit (or, in some cases, a single grouping of target qubits) sees both light beams.

Furthermore, while Equation 4 (as well as Expression 1 and Equations 1-3) describe a case with two light beams, in some cases, more than two light beams may be used to selectively address a single target qubit (or, in some cases, a single grouping of target qubits). Equation 5 provides the general form for three light beams intersecting at arbitrary angles.

$${U}_{target} = [ {A}^{- 1} ] [ {B}^{- 1} ] [ {C}^{- 1} ] [ A ] [ B ] [ C ] , \qquad ( Equation 5 )$$

which may be extended to the case of N light beams intersecting at arbitrary angles in Equation 6. Equations 5 and 6 further describe how, in some cases, order of application of the operators may be important (e.g., via interspersing or interweaving application of the operators in a manner parallel to that described with respect to Equation 4).

$${U}_{target} = [ {A}^{- 1} ] [ {B}^{- 1} ] [ {C}^{- 1} ] … [ {N}^{- 1} ] [ A ] [ B ] [ C ] … [ N ] . \qquad ( Equation 6 )$$

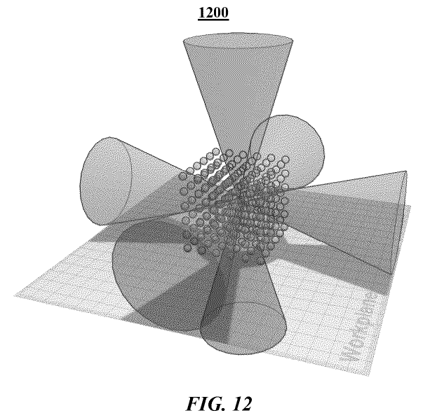

FIG. 12 illustrates an example diagram 1200 of three light beams addressing a target qubit. As illustrated in FIG. 12, only a single target qubit sees all three light beams, while each of the remaining qubits in the array see either only one of the three light beams or none of the three light beams. Accordingly, in FIG. 12, the target qubit may undergo a rotation, θ, while all the remaining qubits in the array undergo no rotation (e.g., via the identity operation, I). Advantageously, using three light beams to address the target qubit may enable cancelling out momentum (e.g., linear momentum) of the target qubit. The three light beams may be non-orthogonal and intersect at an angle selected to cancel momentums (e.g., as described in Hong, T., Cramer, C., Nagourney, W., & Fortson, E. N. (2005). Optical clocks based on Ultranarrow three-photon resonances in alkaline earth atoms. Physical Review Letters, 94(5). https://doi.org/10.1103/physrevlett.94.050801, the disclosure of which is hereby incorporated by reference for all purposes).

### Example Multiple Target Qubit Addressin in a Qubit Array

Although FIG. 10 illustrates the light beams 1010 and 1020 as intersecting at a single qubit, the target qubit 230, in some cases, the light beams 1010 and 1020 may intersect over a plurality of target qubits. Three example configurations in which the light beams 1010 and 1020 may intersect over a plurality of target qubits are provided below.

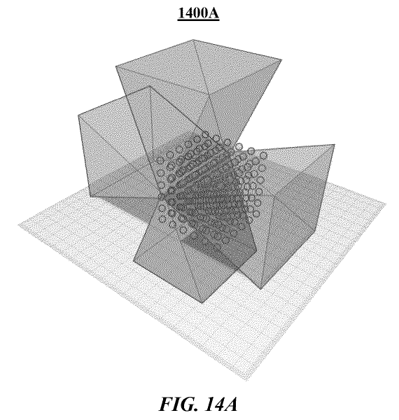

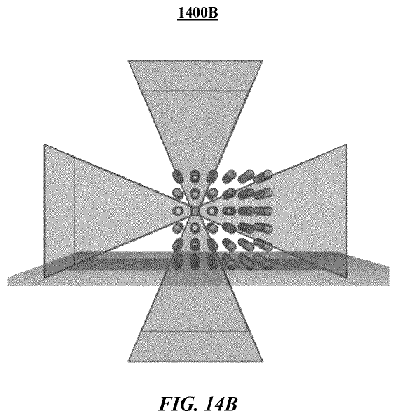

In a first example, the plurality of target qubits may be in a line, forming a one-dimensional target subset of qubits of the overall three-dimensional array of qubits. To achieve this, (1) the light beam 1010 may be a two-dimensional plane of light applied to a two-dimensional sub-array of qubits of the overall three-dimensional array of qubits and (2) the light beam 1020 may be a one-dimensional beam of light that lies in the two-dimensional plane and that is applied to a one-dimensional sub-array of qubits of the two-dimensional sub-array of qubits. Accordingly, the one-dimensional sub-array of qubits may undergo a rotation as the one-dimensional target subset of qubits of the overall three-dimensional array of qubits. Further, the two-dimensional sub-array of qubits that are not the one-dimensional sub-array of qubits may undergo the identity operation, without rotation. In some cases, the two-dimensional plane of light of the light beam 1010 may comprise one or more individual light beams (e.g., lined up next to each other). The configuration of FIGS. 14A and 14B shows a different configuration that also achieves selection of a one-dimensional “line” of target qubits. As illustrated in the diagrams 1400A and 1400B of FIGS. 14A and 14B, respectively, two light beams with foci elongated along a single direction address a line of target qubits.

In a second example, the plurality of target qubits may be in a plane, forming a two-dimensional target subset of qubits of the overall three-dimensional array of qubits. To achieve this, (1) the light beam 1010 may be a two-dimensional plane of light applied to a first two-dimensional sub-array of qubits of the overall three-dimensional array of qubits and (2) the light beam 1020 may be a two-dimensional plane of light applied to a second two-dimensional sub-array of qubits of the overall three-dimensional array of qubits. The first two-dimensional sub-array of qubits and the second two-dimensional sub-array of qubits may overlap over a third two-dimensional sub-array of qubits. Accordingly, the third two-dimensional sub-array of qubits may undergo a rotation as the two-dimensional target subset of qubits of the overall three-dimensional array of qubits. Further, the first two-dimensional sub-array of qubits and the second two-dimensional sub-array of qubits that are not the third two-dimensional sub-array of qubits may undergo the identity operation, without rotation. In some cases, the two-dimensional plane of light of the light beam 1010 or the light beam 1020 may comprise one or more individual light beams (e.g., lined up next to each other).

In a third example, the plurality of target qubits may be in a three-dimensional arrangement, forming a three-dimensional target subset of the overall three-dimensional array of qubits. To achieve this, (1) the light beam 1010 may be a three-dimensional beam of light applied to a first three-dimensional sub-array of qubits of the overall three-dimensional array of qubits and (2) the light beam 1020 may be a three-dimensional beam of light applied to a second three-dimensional sub-array of qubits of the overall three-dimensional array of qubits. The first three-dimensional sub-array of qubits and the second three-dimensional sub-array of qubits may overlap over a third three-dimensional sub-array of qubits. Accordingly, the third three-dimensional sub-array of qubits may undergo a rotation as the three-dimensional target subset of qubits of the overall three-dimensional array of qubits. Further, the first three-dimensional sub-array of qubits and the second three-dimensional sub-array of qubits that are not the third three-dimensional sub-array of qubits may undergo the identity operation, without rotation. In some cases, the three-dimensional beam of light of the light beam 1010 or the light beam 1020 may comprise one or more individual light beams (e.g., arranged nearby each other).

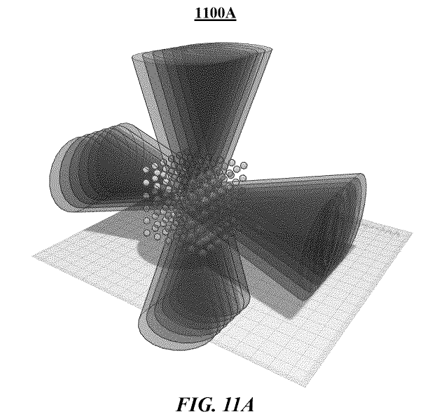

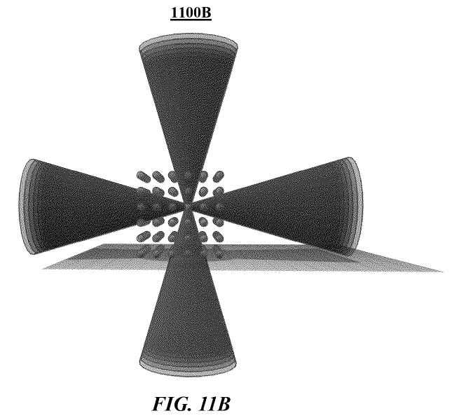

Additional examples of addressing a plurality of qubits are disclosed herein with respect to FIGS. 11A and 11B.

In some cases, gates (e.g., laser beams) on multiple target qubits can be driven in parallel provided the introduction of new addressing beams does not cause any neighboring qubits to see addressing light from more than one direction. Therefore, the systems, the methods, the computer-readable media, and the techniques described herein may drive parallel operations on at least “N” qubits in an N×N×N array, since doing so may create a single line of qubits within the N×N×N array that see both light beams in a pair, while all other qubits see either no light beam or a single light beam in a pair. FIGS. 11A and 11B depict, from two different perspectives, a plurality of pairs of orthogonal light beams, each pair of orthogonal light beams addressing a target qubit in a single line of target qubits within a 3-dimensional array. Further, as illustrated, each pair of light beams lie along a 2-dimensional plane that does not intersect, at least over the array of qubits, with the 2-dimensional plane that each of the other pairs of light beams lie along.

In some cases, driving parallel operations on N² gates in parallel for an array of N×N×N qubits may be possible. For example, driving parallel operations on N² gates in parallel may be accomplished by applying a global beam that has the capability of illuminating only a single plane of the N×N×N array without contaminating other planes with light. This global beam may be tasked, for example, with performing π rotations about the y-axis, while site-resolved beams from the perpendicular direction may be tasked with performing arbitrary rotations about the x-axis for each qubit.

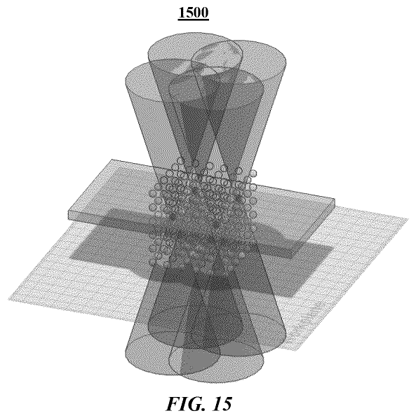

FIG. 15 illustrates an example diagram 1500 of four light beams and a planar light beam (e.g., “light sheet”) addressing four target qubits. The configuration of the diagram 1500 enables selecting four target qubits that are in the same plane via using a light sheet and four light beams.

The light beams of the systems, the methods, the computer-readable media, and the techniques disclosed herein may comprise one or more of a substantially conical profile (e.g., as illustrated in FIGS. 11A-13), a substantially triangular prism profile (e.g., as illustrated in FIGS. 14A and 14B), a substantially rectangular prism profile, a substantially planar profile (e.g., as illustrated in FIG. 15), a substantially cylindrical profile, a substantially pyramidal profile, etc. In some cases, the light beams may have a focus elongated in one direction. In some cases, the light beams may have a focus elongated in two directions. In some cases, the light beams may have a focus elongated in three dimensions.

In some cases, the target qubit or target qubits may each be addressed by a plurality of light beams (e.g., two light beams as illustrated in FIGS. 10-11B and 13-15, three light beams as illustrated in FIG. 12, four light beams, five light beams, etc.) where each light beam of the plurality of light beams comprises two invertible operations. In some cases, the plurality of light beams addressing the target qubit or target qubits comprises 2 light beams to about 50 light beams. In some cases, the plurality of light beams addressing the target qubit or target qubits comprises 2 light beams to 3 light beams, 2 light beams to 4 light beams, 2 light beams to 5 light beams, 2 light beams to 6 light beams, 2 light beams to 7 light beams, 2 light beams to 8 light beams, 2 light beams to 9 light beams, 2 light beams to about 10 light beams, 2 light beams to about 15 light beams, 2 light beams to about 25 light beams, 2 light beams to about 50 light beams, 3 light beams to 4 light beams, 3 light beams to 5 light beams, 3 light beams to 6 light beams, 3 light beams to 7 light beams, 3 light beams to 8 light beams, 3 light beams to 9 light beams, 3 light beams to about 10 light beams, 3 light beams to about 15 light beams, 3 light beams to about 25 light beams, 3 light beams to about 50 light beams, 4 light beams to 5 light beams, 4 light beams to 6 light beams, 4 light beams to 7 light beams, 4 light beams to 8 light beams, 4 light beams to 9 light beams, 4 light beams to about 10 light beams, 4 light beams to about 15 light beams, 4 light beams to about 25 light beams, 4 light beams to about 50 light beams, 5 light beams to 6 light beams, 5 light beams to 7 light beams, 5 light beams to 8 light beams, 5 light beams to 9 light beams, 5 light beams to about 10 light beams, 5 light beams to about 15 light beams, 5 light beams to about 25 light beams, 5 light beams to about 50 light beams, 6 light beams to 7 light beams, 6 light beams to 8 light beams, 6 light beams to 9 light beams, 6 light beams to about 10 light beams, 6 light beams to about 15 light beams, 6 light beams to about 25 light beams, 6 light beams to about 50 light beams, 7 light beams to 8 light beams, 7 light beams to 9 light beams, 7 light beams to about 10 light beams, 7 light beams to about 15 light beams, 7 light beams to about 25 light beams, 7 light beams to about 50 light beams, 8 light beams to 9 light beams, 8 light beams to about 10 light beams, 8 light beams to about 15 light beams, 8 light beams to about 25 light beams, 8 light beams to about 50 light beams, 9 light beams to about 10 light beams, 9 light beams to about 15 light beams, 9 light beams to about 25 light beams, 9 light beams to about 50 light beams, about 10 light beams to about 15 light beams, about 10 light beams to about 25 light beams, about 10 light beams to about 50 light beams, about 15 light beams to about 25 light beams, about 15 light beams to about 50 light beams, or about 25 light beams to about 50 light beams. In some cases, the plurality of light beams addressing the target qubit or target qubits comprises 2 light beams, 3 light beams, 4 light beams, 5 light beams, 6 light beams, 7 light beams, 8 light beams, 9 light beams, about 10 light beams, about 15 light beams, about 25 light beams, or about 50 light beams. In some cases, the plurality of light beams addressing the target qubit or target qubits comprises at least 2 light beams, 3 light beams, 4 light beams, 5 light beams, 6 light beams, 7 light beams, 8 light beams, 9 light beams, about 10 light beams, about 15 light beams, or about 25 light beams. In some cases, the plurality of light beams addressing the target qubit or target qubits comprises at most 3 light beams, 4 light beams, 5 light beams, 6 light beams, 7 light beams, 8 light beams, 9 light beams, about 10 light beams, about 15 light beams, about 25 light beams, or about 50 light beams.

### Example Cross-Talk Considerations

In some cases, the use cases illustrated in FIGS. 10, 11A 11B, and 12 operate provided the divergence angle of the addressing beams is smaller than 45 degrees, which may be typically the case for standard microscope objectives with numerical apertures<0.7. If both addressing beams possess divergence angles larger than 45 degrees, then the “diagonal nearest neighbors” of the target qubits may also see non-negligible amounts of light from both addressing beams.

In some cases, unwanted cross-talk may be largest for qubits which are diagonal nearest-neighbors from a target qubit, since they may see equal amounts of leakage light from both of the orthogonal light beams. However, proper optical engineering may reduce the leakage light seen by neighboring qubits to be arbitrarily small.

Furthermore, in some cases, particularly those with an extremely small rotation angle, rotations about different axes commute. Therefore, if the cross-talk-induced rotation is made to be small enough, then to first-order, the unwanted rotations may be canceled after all pulses are complete. This offers a further factor of suppression of unwanted cross-talk beyond what might be expected from simply minimizing intensity at neighboring qubits.

### Example Doppler-Free and Recoil-Free Driving of Gates

In some cases, two-photon Raman transitions can be used to drive transitions between qubit states whose frequency separation is much smaller than the optical frequency of the addressing beams. In this case, the operations which are driven may result in a negligible change of the target qubit's momentum state compared to the momenta of the driving photons. This may be important because the coupling of internal and external degrees of freedom of the qubit may result in loss of fidelity if the external degrees of freedom are not precisely controlled.

K. Barnes et al., “Assembly and coherent control of a register of nuclear spin qubits”. Nature Communications, 13(1) (2022) describes a technique for implementing Doppler- and recoil-free single qubit gates. Specifically, in some cases, the orientation of the rotation axis can be controlled by the relative phase between the co-propagating Raman beams. A phase difference of (φ) and

$$( ϕ + \frac{π}{2} )$$

between the two beams may enable rotating around the x-axis or y-axis.

### Example Targeted Driving of Qubits to States Outside the Qubit Subspace

The systems, the methods, the computer-readable media, and the techniques described herein can be used to coherently drive target qubits to arbitrary states, even if those states do not lie within the manifold describing the qubit subspace. For example, the systems, the methods, the computer-readable media, and the techniques described herein may enable driving qubits to the “clock state” (³P₀), which is outside the qubit subspace (which includes the m_{F}=−½, +½ states of ¹S₀), but may nonetheless be used, e.g., for the first leg of Rydberg gate schemes and for certain readout protocols.

For the specific case of ytterbium, rotations may be driven between the qubit subspace and ³P₀ using a 1-photon transition at about 578 nanometers. Rotation about the x-axis and y-axis may be driven from perpendicular directions as was described above, and the rotation axis may be changed by updating the phase of the addressing laser between pulses.

### Example Methods Addressing Qubits

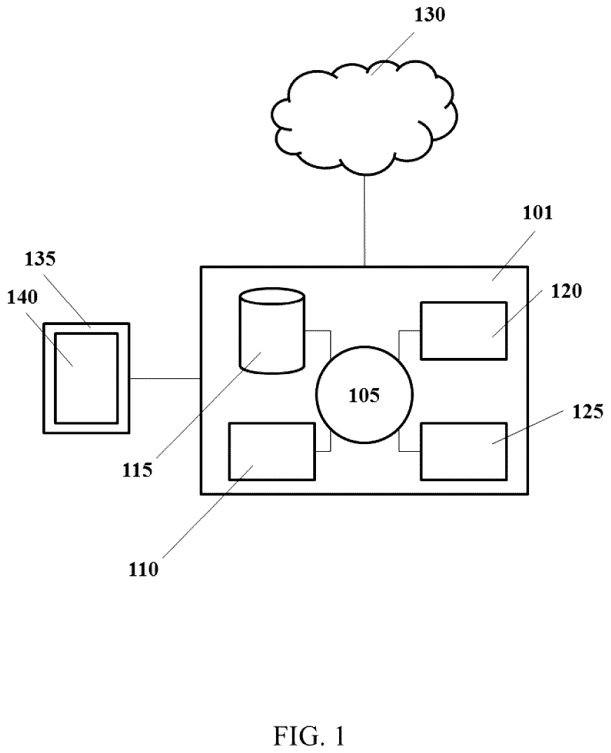

The systems, the methods, the computer-readable media, and the techniques of the present disclosure can be implemented by way of one or more algorithms. The one or more algorithms can be implemented by way of software upon execution by the central processing unit 105 of FIG. 1.

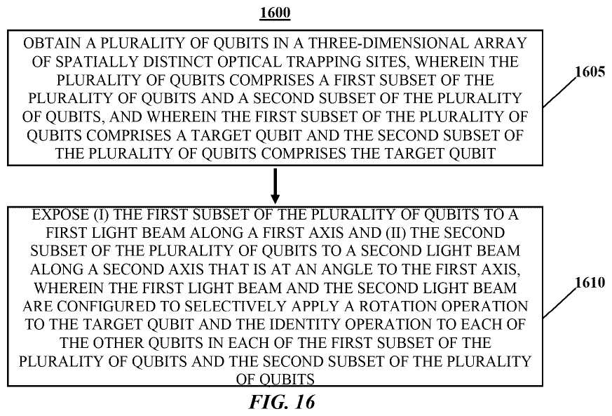

A first algorithm of the one or more algorithms can, for example, implement method 1600 of FIG. 16 that includes: obtaining a plurality of qubits in a three-dimensional array of spatially distinct optical trapping sites, wherein the plurality of qubits comprises a first subset of the plurality of qubits and a second subset of the plurality of qubits, and wherein the first subset of the plurality of qubits comprises a target qubit and the second subset of the plurality of qubits comprises the target qubit (block 1605); and exposing (i) the first subset of the plurality of qubits to a first light beam along a first axis and (ii) the second subset of the plurality of qubits to a second light beam along a second axis that is at an angle to the first axis, wherein the first light beam and the second light beam are configured to selectively apply a rotation operation to the target qubit and the identity operation to each of the other qubits in each of the first subset of the plurality of qubits and the second subset of the plurality of qubits (block 1610).

In some cases, the method 1600 may further include exposing (i) a third subset of the plurality of qubits to a third light beam along a third axis that is parallel or skew to the first axis and (ii) a fourth subset of the plurality of qubits to a fourth light beam along a fourth axis that is parallel or skew to the second axis, wherein the third light beam and the fourth light beam are configured to selectively apply a second rotation operation to a second target qubit and the identity operation to each of the other qubits in each of the third subset of the plurality of qubits and the fourth subset of the plurality of qubits, wherein the third subset of the plurality of qubits comprises the second target qubit and the fourth subset of the plurality of qubits comprises the second target qubit. While not illustrated in the method 1600, this operation may be the same as or similar to the gate parallelization disclosed herein with respect to FIGS. 11A and 11B.

In some cases, the block 1610 of method 1600 may further include exposing a third subset of the plurality of qubits to a third light beam along a third axis, wherein: (i) the third subset of the plurality of qubits comprises the target qubit, (ii) the third light beam is configured to selectively apply a rotation operation to the target qubit and the identity operation to each of the other qubits in each of the first subset of the plurality of qubits and the second subset of the plurality of qubits, and (iii) each of the first subset of the plurality of qubits, the second subset of the plurality of qubits, and the third subset of the plurality of qubits are, with exception for the target qubit, mutually exclusive with respect to one another. While not illustrated in the method 1600, this operation may be the same as or similar to the gate parallelization disclosed herein with respect to FIG. 12.

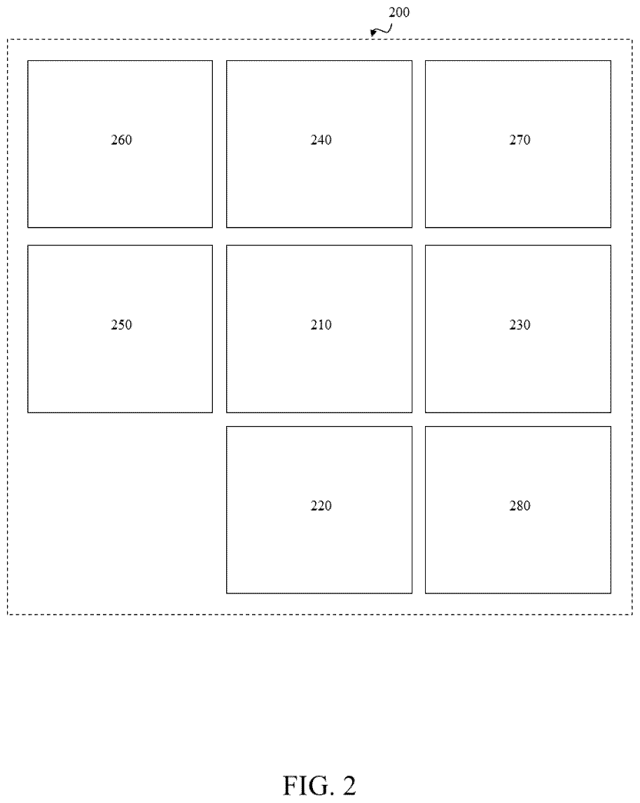

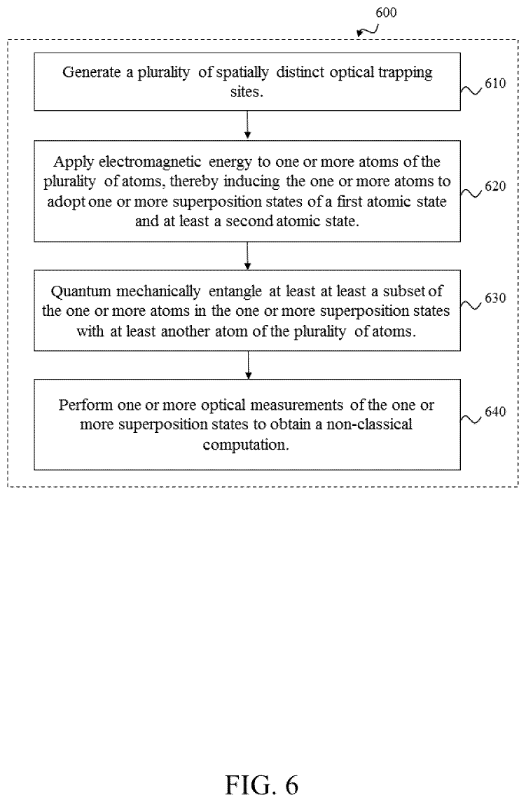

In some cases, the method 1600 may further include performing a non-classical computation based at least in part on selectively applying the rotation operation to the target qubit at block 1605. While not illustrated in the method 1600, this operation may perform the non-classical computation using a system that may be the same as or similar to one or more components of the system 200 for performing a non-classical computation of FIG. 2. Further, this operation to perform the non-classical computation may be the same as or similar to one or more operations of at least one of the methods 600, 700, or 800 for performing a non-classical computation of FIGS. 6-8.

The one or more operations disclosed above with respect to the method 1600 (both operations illustrated in FIG. 16 and not illustrated) may be performed in any order. Further, at least one of the one or more operations disclosed above with respect to the method 1600 may be repeated, e.g., iteratively.

### Example of Systems for Performing a Non-Classical Computation

FIG. 2 shows an example of a system 200 for performing a non-classical computation. The non-classical computation may comprise a quantum computation. The quantum computation may comprise a gate-model quantum computation.

The system 200 may comprise one or more trapping units 210. The trapping units may comprise one or more optical trapping units. The optical trapping units may comprise any optical trapping unit described herein, such as an optical trapping unit described herein with respect to FIG. 3A. The optical trapping units may be configured to generate a plurality of optical trapping sites. The optical trapping units may be configured to generate a plurality of spatially distinct optical trapping sites. For instance, the optical trapping units may be configured to generate at least about 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more optical trapping sites. The optical trapping units may be configured to generate at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, or fewer optical trapping sites. The optical trapping units may be configured to trap a number of optical trapping sites that is within a range defined by any two of the preceding values.

The optical trapping units may be configured to trap a plurality of atoms. For instance, the optical trapping units may be configured to trap at least about 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more atoms. The optical trapping units may be configured to trap at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, or fewer atoms. The optical trapping units may be configured to trap a number of atoms that is within a range defined by any two of the preceding values.

Each optical trapping site of the optical trapping units may be configured to trap at least about 1, 2, 3, 4, 5, 6, 7, 8, 9, 10, or more atoms. Each optical trapping site may be configured to trap at most about 10, 9, 8, 7, 6, 5, 4, 3, 2, 1, or fewer atoms. Each optical trapping site may be configured to trap a number of atoms that is within a range defined by any two of the preceding values. Each optical trapping site may be configured to trap a single atom.

One or more atoms of the plurality of atoms may comprise qubits, as described herein (for instance, with respect to FIG. 4). Two or more atoms may be quantum mechanically entangled. Two or more atoms may be quantum mechanically entangled with a coherence lifetime of at least about 1 microsecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, 200 μs, 300 μs, 400 μs, 500 μs, 600 μs, 700 μs, 800 μs, 900 μs, 1 millisecond (ms), 2 ms, 3 ms, 4 ms, 5 ms, 6 ms, 7 ms, 8 ms, 9 ms, 10 ms, 20 ms, 30 ms, 40 ms, 50 ms, 60 ms, 70 ms, 80 ms, 90 ms, 100 ms, 200 ms, 300 ms, 400 ms, 500 ms, 600 ms, 700 ms, 800 ms, 900 ms, 1 second (s), 2 s, 3 s, 4 s, 5 s, 6 s, 7 s, 8 s, 9 s, 10 s, or more. Two or more atoms may be quantum mechanically entangled with a coherence lifetime of at most about 10 s, 9 s, 8 s, 7 s, 6 s, 5 s, 4 s, 3 s, 2 s, 1 s, 900 ms, 800 ms, 700 ms, 600 ms, 500 ms, 400 ms, 300 ms, 200 ms, 100 ms, 90 ms, 80 ms, 70 ms, 60 ms, 50 ms, 40 ms, 30 ms, 20 ms, 10 ms, 9 ms, 8 ms, 7 ms, 6 ms, 5 ms, 4 ms, 3 ms, 2 ms, 1 ms, 900 μs, 800 μs, 700 μs, 600 μs, 500 μs, 400 μs, 300 μs, 200 μs, 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, or less. Two or more atoms may be quantum mechanically entangled with a coherence lifetime that is within a range defined by any two of the preceding values. One or more atoms may comprise neutral atoms. One or more atoms may comprise uncharged atoms.

One or more atoms may comprise alkali atoms. One or more atoms may comprise lithium (Li) atoms, sodium (Na) atoms, potassium (K) atoms, rubidium (Rb) atoms, or cesium (Cs) atoms. One or more atoms may comprise lithium-6 atoms, lithium-7 atoms, sodium-23 atoms, potassium-39 atoms, potassium-40 atoms, potassium-41 atoms, rubidium-85 atoms, rubidium-87 atoms, or caesium-133 atoms. One or more atoms may comprise alkaline earth atoms. One or more atoms may comprise beryllium (Be) atoms, magnesium (Mg) atoms, calcium (Ca) atoms, strontium (Sr) atoms, or barium (Ba) atoms. One or more atoms may comprise beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, or barium-138 atoms. One or more atoms may comprise rare earth atoms. One or more atoms may comprise scandium (Sc) atoms, yttrium (Y) atoms, lanthanum (La) atoms, cerium (Ce) atoms, praseodymium (Pr) atoms, neodymium (Nd) atoms, samarium (Sm) atoms, europium (Eu) atoms, gadolinium (Gd) atoms, terbium (Tb) atoms, dysprosium (Dy) atoms, holmium (Ho) atoms, erbium (Er) atoms, thulium (Tm) atoms, ytterbium (Yb) atoms, or lutetium (Lu) atoms. One or more atoms may comprise scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms.

The plurality of atoms may comprise a single element selected from the group consisting of Li, Na, K, Rb, Cs, Be, Mg, Ca, Sr, and Ba. The plurality of atoms may comprise a mixture of elements selected from the group consisting of Li, Na, K, Rb, Cs, Be, Mg, Ca, Sr, and Ba. The plurality of atoms may comprise a natural isotopic mixture of one or more elements selected from the group consisting of Li, Na, K, Rb, Cs, Be, Mg, Ca, Sr, and Ba. The plurality of atoms may comprise an isotopically enriched mixture of one or more elements selected from the group consisting of Li, Na, K, Rb, Cs, Be, Mg, Ca, Sr, and Ba. The plurality of atoms may comprise a natural isotopic mixture of one or more elements selected from the group consisting of Sc, Y, La, Ce, Pr, Nd, Sm, Eu, Gd, Tb, Dy, Ho, Er, Tm, Yb, and Lu. The plurality of atoms may comprise an isotopically enriched mixture of one or more elements selected from the group consisting of Sc, Y, La, Ce, Pr, Nd, Sm, Eu, Gd, Tb, Dy, Ho, Er, Tm, Yb, and Lu. atoms may comprise rare earth atoms. For instance, the plurality of atoms may comprise lithium-6 atoms, lithium-7 atoms, sodium-23 atoms, potassium-39 atoms, potassium-40 atoms, potassium-41 atoms, rubidium-85 atoms, rubidium-87 atoms, caesium-133 atoms, beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, barium-138 atoms, scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms enriched to an isotopic abundance of at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, 99.91%, 99.92%, 99.93%, 99.94%, 99.95%, 99.96%, 99.97%, 99.98%, 99.99%, or more. The plurality of atoms may comprise lithium-6 atoms, lithium-7 atoms, sodium-23 atoms, potassium-39 atoms, potassium-40 atoms, potassium-41 atoms, rubidium-85 atoms, rubidium-87 atoms, caesium-133 atoms, beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, barium-138 atoms, scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms enriched to an isotopic abundance of at most about 99.99%, 99.98%, 99.97%, 99.96%, 99.95%, 99.94%, 99.93%, 99.92%, 99.91%, 99.9%, 99.8%, 99.7%, 99.6%, 99.5%, 99.4%, 99.3%, 99.2%, 99.1%, 99%, 98%, 97%, 96%, 95%, 94%, 93%, 92%, 91%, 90%, 80%, 70%, 60%, 50%, or less. The plurality of atoms may comprise lithium-6 atoms, lithium-7 atoms, sodium-23 atoms, potassium-39 atoms, potassium-40 atoms, potassium-41 atoms, rubidium-85 atoms, rubidium-87 atoms, caesium-133 atoms, beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, barium-138 atoms, scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms enriched to an isotopic abundance that is within a range defined by any two of the preceding values.

The system 200 may comprise one or more first electromagnetic delivery units 220. The first electromagnetic delivery units may comprise any electromagnetic delivery unit described herein, such as an electromagnetic delivery unit described herein with respect to FIG. 4. The first electromagnetic delivery units may be configured to apply first electromagnetic energy to one or more atoms of the plurality of atoms. Applying the first electromagnetic energy may induce the atoms to adopt one or more superposition states of a first atomic state and a second atomic state that is different from the first atomic state.

The first atomic state may comprise a first single-qubit state. The second atomic state may comprise a second single-qubit state. The first atomic state or second atomic state may be elevated in energy with respect to a ground atomic state of the atoms. The first atomic state or second atomic state may be equal in energy with respect to the ground atomic state of the atoms.

The first atomic state may comprise a first hyperfine electronic state and the second atomic state may comprise a second hyperfine electronic state that is different from the first hyperfine electronic state. For instance, the first and second atomic states may comprise first and second hyperfine states on a multiplet manifold, such as a triplet manifold. The first and second atomic states may comprise first and second hyperfine states, respectively, on a ³P₁ or ³P₂ manifold. The first and second atomic states may comprise first and second hyperfine states, respectively, on a ³P₁ or ³P₂ manifold of any atom described herein, such as a strontium-87 ³P₁ manifold or a strontium-87 ³P₂ manifold.

In some cases, the first and second atomic states are first and second hyperfine states of a first electronic state. Optical excitation may be applied between a first electronic state and a second electronic state. The optical excitation may excite the first hyperfine state and/or the second hyperfine state to the second electronic state. A single-qubit transition may comprise a two-photon transition between two hyperfine states within the first electronic state using a second electronic state as an intermediate state. To drive a single-qubit transition, a pair of frequencies, each detuned from a single-photon transition to the intermediate state, may be applied to drive a two-photon transition. In some cases, the first and second hyperfine states are hyperfine states of the ground electronic state. The ground electronic state may not decay by spontaneous or stimulated emission to a lower electronic state. The hyperfine states may comprise nuclear spin states.

In some cases, the hyperfine states comprise nuclear spin states of a strontium-87 ¹S₀ manifold and the qubit transition drives one or both of two nuclear spin states of strontium-87 ¹S₀ to a state detuned from or within the ³P₂ or ³P₁ manifold. In some cases, the one-qubit transition is a two photon Raman transition between nuclear spin states of strontium-87 ¹S₀ via a state detuned from or within the ³P₂ or ³P₁ manifold. In some cases, the nuclear spin states may be Stark shifted nuclear spin states. A Stark shift may be driven optically. An optical Stark shift may be driven off resonance with any, all, or a combination of a single-qubit transition, a two-qubit transition, a shelving transition, an imaging transition, etc.

In some cases, the hyperfine states comprise nuclear spin states of a ytterbium

The first atomic state may comprise a first nuclear spin state and the second atomic state may comprise a second nuclear spin state that is different from the first nuclear spin state. The first and second atomic states may comprise first and second nuclear spin states, respectively, of a quadrupolar nucleus. The first and second atomic states may comprise first and second nuclear spin states, respectively, of a spin-1, spin-3/2, spin-2, spin-5/2, spin-3, spin-7/2, spin-4, or spin-9/2 nucleus. The first and second atomic states may comprise first and second nuclear spin states, respectively, of any atom described herein, such as first and second spin states of strontium-87.

For first and second nuclear spin states associated with a nucleus comprising a spin greater than 1/2 (such as a spin-1, spin-3/2, spin-2, spin-5/2, spin-3, spin-7/2, spin-4, or spin-9/2 nucleus), transitions between the first and second nuclear spin states may be accompanied by transitions between other spin states on the nuclear spin manifold. For instance, for a spin-9/2 nucleus in the presence of a uniform magnetic field, all of the nuclear spin levels may be separated by equal energy. Thus, a transition (such as a Raman transition) designed to transfer atoms from, for instance, an m_{N}=9/2 spin state to an m_{N}=7/2 spin state, may also drive m_{N}=7/2 to m_{N}=5/2, m_{N}=5/2 to m_{N}=3/2, m_{N}=3/2 to m_{N}=1/2, m_{N}=1/2 to m_{N}=−1/2, m_{N}=−1/2 to m_{N}=−3/2, m_{N}=−3/2 to m_{N}=−5/2, m_{N}=−5/2 to m_{N}=−7/2, and m_{N}=−7/2 to m_{N}=−9/2, where m_{N} is the nuclear spin state. Similarly, a transition (such as a Raman transition) designed to transfer atoms from, for instance, an m_{N}=9/2 spin state to an m_{N}=5/2 spin state, may also drive m_{N}=7/2 to m_{N}=3/2, m_{N}=5/2 to m_{N}=1/2, m_{N}=3/2 to m_{N}=−1/2, m_{N}=1/2 to m_{N}=−3/2, m_{N}=−1/2 to m_{N}=−5/2, m_{N}=−3/2 to m_{N}=−7/2, and m_{N}=−5/2 to m_{N}=−9/2. Such a transition may thus not be selective for inducing transitions between particular spin states on the nuclear spin manifold.

It may be desirable to instead implement selective transitions between particular first and second spins states on the nuclear spin manifold. This may be accomplished by providing light from a light source that provides an AC Stark shift and pushes neighboring nuclear spin states out of resonance with a transition between the desired transition between the first and second nuclear spin states. For instance, if a transition from first and second nuclear spin states having m_{N}=−9/2 and m_{N}=−7/2 is desired, the light may provide an AC Stark shift to the m_{N}=−5/2 spin state, thereby greatly reducing transitions between the m_{N}=−7/2 and m_{N}=−5/2 states. Similarly, if a transition from first and second nuclear spin states having m_{N}=−9/2 and m_{N}=−5/2 is desired, the light may provide an AC Stark shift to the m_{N}=−1/2 spin state, thereby greatly reducing transitions between the m_{N}=−5/2 and m_{N}=−1/2 states. This may effectively create a two-level subsystem within the nuclear spin manifold that is decoupled from the remainder of the nuclear spin manifold, greatly simplifying the dynamics of the qubit systems. It may be advantageous to use nuclear spin states near the edge of the nuclear spin manifold (e.g., m_{N}=−9/2 and m_{N}=−7/2, m_{N}=7/2 and m_{N}=9/2, m_{N}=−9/2 and m_{N}=−5/2, or m_{N}=5/2 and m_{N}=9/2 for a spin-9/2 nucleus) such that only one AC Stark shift is required. Alternatively, nuclear spin states farther from the edge of the nuclear spin manifold (e.g., m_{N}=−5/2 and m_{N}=−3/2 or m_{N}=−5/2 and m_{N}=−1/2) may be used and two AC Stark shifts may be implemented (e.g., at m_{N}=−7/2 and m_{N}=−1/2 or m_{N}=−9/2 and m_{N}=3/2).

Stark shifting of the nuclear spin manifold may shift neighboring nuclear spin states out of resonance with the desired transition between the first and second nuclear spin states and a second electronic state or a state detuned therefrom. Stark shifting may decrease leakage from the first and second nuclear spin state to other states in the nuclear spin manifold. Starks shifts may be achievable up to 100s of kHz for less than 10 mW beam powers. Upper state frequency selectivity may decrease scattering from imperfect polarization control. Separation of different angular momentum states in the ³P₁ manifold may be many gigahertz from the single and two-qubit gate light. Leakage to other states in the nuclear spin manifold may lead to decoherence. The Rabi frequency for two-qubit transitions (e.g., how quickly the transition can be driven) may be faster than the decoherence rate. Scattering from the intermediate state in the two-qubit transition may be a source of decoherence. Detuning from the intermediate state may improve fidelity of two-qubit transitions.

Qubits based on nuclear spin states in the electronic ground state may allow exploitation of long-lived metastable excited electronic states (such as a ³P₀ state in strontium-87) for qubit storage. Atoms may be selectively transferred into such a state to reduce cross-talk or to improve gate or detection fidelity. Such a storage or shelving process may be atom-selective using the SLMs or AODs described herein. A shelving transition may comprise a transition between the ¹S₀ state in strontium-87 to the ³P₀ or ³P₂ state in strontium-87.

The clock transition (also a “shelving transition” or a “storage transition” herein) may be qubit-state selective. The upper state of the clock transition may have a very long natural lifetime, e.g., greater than 1 second. The linewidth of the clock transition may be much narrower than the qubit energy spacing. This may allow direct spectral resolution. Population may be transferred from one of the qubit states into the clock state. This may allow individual qubit states to be read out separately, by first transferring population from one qubit state into the clock state, performing imaging on the qubits, then transferring the population back into the ground state from the clock state and imaging again. In some cases, a magic wavelength transition is used to drive the clock transition.

The clock light for shelving can be atom-selective or not atom-selective. In some cases, the clock transition is globally applied (e.g., not atom selective). A globally applied clock transition may include directing the light without passing through a microscope objective or structuring the light. In some cases, the clock transition is atom-selective. Clock transition which are atom-selective may potentially allow us to improve gate fidelities by minimizing cross-talk. For example, to reduce cross talk in an atom, the atom may be shelved in the clock state where it may not be affected by the light. This may reduce cross-talk between neighboring qubits undergoing transitions. To implement atom-selective clock transitions, the light may pass through one or more microscope objectives and/or may be structured on one or more of a spatial light modulator, digital micromirror device, crossed acousto-optic deflectors, etc.

The system 200 may comprise one or more readout units 230. The readout units may comprise one or more readout optical units. The readout optical units may be configured to perform one or more measurements of the one or more superposition states to obtain the non-classical computation. The readout optical units may comprise one or more optical detectors. The detectors may comprise one or more photomultiplier tubes (PMTs), photodiodes, avalanche diodes, single-photon avalanche diodes, single-photon avalanche diode arrays, phototransistors, reverse-biased light emitting diodes (LEDs), charge coupled devices (CCDs), or complementary metal oxide semiconductor (CMOS) cameras. The optical detectors may comprise one or more fluorescence detectors. The readout optical unit may comprise one or more objectives, such as one or more objective having a numerical aperture (NA) of at least about 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, or more. The objective may have an NA of at most about 1, 0.95, 0.9, 0.85, 0.8, 0.75, 0.7, 0.65, 0.6, 0.55, 0.5, 0.45, 0.4, 0.35, 0.3, 0.25, 0.2, 0.15, 0.1, or less. The objective may have an NA that is within a range defined by any two of the preceding values.

The one or more readout optical units 230 may make measurements, such as projective measurements, by applying light resonant with an imaging transition. The imaging transition may cause fluorescence. An imaging transition may comprise a transition between the ¹S₀ state in strontium-87 to the ¹P₁ state in strontium-87. The ¹P₁ state in strontium-87 may fluoresce. The lower state of the qubit transition may comprise two nuclear spin states in the ¹S₀ manifold. The one or more states may be resonant with the imaging transition. A measurement may comprise two excitations. In a first excitation, one of the two lower states may be excited to the shelving state (e.g., ³P₀ state in strontium-87). In a second excitation, the imaging transition may be excited. The first transition may reduce cross-talk between neighboring atoms during computation. Fluorescence generated from the imaging transition may be collected on one or more readout optical units 230.

The imaging units may be used to determine if one or more atoms were lost from the trap. The imaging units may be used to observe the arrangement of atoms in the trap.

The system 200 may comprise one or more vacuum units 240. The one or more vacuum units may comprise one or more vacuum pumps. The vacuum units may comprise one or more roughing vacuum pumps, such as one or more rotary pumps, rotary vane pumps, rotary piston pumps, diaphragm pumps, piston pumps, reciprocating piston pumps, scroll pumps, or screw pumps. The one or more roughing vacuum pumps may comprise one or more wet (for instance, oil-sealed) or dry roughing vacuum pumps. The vacuum units may comprise one or more high-vacuum pumps, such as one or more cryosorption pumps, diffusion pumps, turbomolecular pumps, molecular drag pumps, turbo-drag hybrid pumps, cryogenic pumps, ions pumps, or getter pumps.

The vacuum units may comprise any combination of vacuum pumps described herein. For instance, the vacuum units may comprise one or more roughing pumps (such as a scroll pump) configured to provide a first stage of rough vacuum pumping. The roughing vacuum pumps may be configured to pump gases out of the system 200 to achieve a low vacuum pressure condition. For instance, the roughing pumps may be configured to pump gases out of the system 200 to achieve a low vacuum pressure of at most about 103 Pascals (Pa). The vacuum units may further comprise one or more high-vacuum pumps (such as one or more ion pumps, getter pumps, or both) configured to provide a second stage of high vacuum pumping or ultra-high vacuum pumping. The high-vacuum pumps may be configured to pump gases out of the system 200 to achieve a high vacuum pressure of at most about 10⁻³ Pa or an ultra-high vacuum pressure of at most about 10⁻⁶ Pa once the system 200 has reached the low vacuum pressure condition provided by the one or more roughing pumps.

The vacuum units may be configured to maintain the system 200 at a pressure of at most about 10⁻⁶ Pa, 9×10⁻⁷ Pa, 8×10⁻⁷ Pa, 7×10⁻⁷ Pa, 6×10⁻⁷ Pa, 5×10⁻⁷ Pa, 4×10⁻⁷ Pa, 3×10⁻⁷ Pa, 2×10⁻⁷ Pa, 10⁻⁷ Pa, 9×10⁻⁸ Pa, 8×10⁻⁸ Pa, 7×10⁻⁸ Pa, 6×10⁻⁸ Pa, 5×10⁻⁸ Pa, 4×10⁻⁸ Pa, 3×10⁻⁸ Pa, 2×10⁻⁸ Pa, 10⁻⁸ Pa, 9×10⁻⁹ Pa, 8×10⁻⁹ Pa, 7×10⁻⁹ Pa, 6×10⁻⁹ Pa, 5×10⁻⁹ Pa, 4×10⁻⁹ Pa, 3×10⁻⁹ Pa, 2×10⁻⁹ Pa, 10⁻⁹ Pa, 9×10⁻¹⁰ Pa, 8×10⁻¹⁰ Pa, 7×10⁻¹⁰ Pa, 6×10⁻¹⁰ Pa, 5×10⁻¹⁰ Pa, 4×10⁻¹⁰ Pa, 3×10⁻¹⁰ Pa, 2×10⁻¹⁰ Pa, 10⁻¹⁰ Pa, 9×10⁻¹¹ Pa, 8×10⁻¹¹ Pa, 7×10⁻¹¹ Pa, 6×10⁻¹¹ Pa, 5×10⁻¹¹ Pa, 4×10⁻¹¹ Pa, 3×10⁻¹¹ Pa, 2×10⁻¹¹ Pa, 10⁻¹¹ Pa, 9×10⁻¹² Pa, 8×10⁻¹² Pa, 7×10⁻¹² Pa, 6×10⁻¹² Pa, 5×10⁻¹² Pa, 4×10⁻¹² Pa, 3×10⁻¹² Pa, 2×10⁻¹² Pa, 10⁻¹² Pa, or lower.

The vacuum units may be configured to maintain the system 200 at a pressure of at least about 10⁻¹² Pa, 2×10⁻¹² Pa, 3×10⁻¹² Pa, 4×10⁻¹² Pa, 5×10⁻¹² Pa, 6×10⁻¹² Pa, 7×10⁻¹² Pa, 8×10⁻¹² Pa, 9×10⁻¹² Pa, 10⁻¹¹ Pa, 2×10⁻¹¹ Pa, 3×10⁻¹¹ Pa, 4×10⁻¹¹ Pa, 5×10⁻¹¹ Pa, 6×10⁻¹¹ Pa, 7×10⁻¹¹ Pa, 8×10⁻¹¹ Pa, 9×10⁻¹¹ Pa, 10⁻¹⁰ Pa, 2×10⁻¹⁰ Pa, 3×10⁻¹⁰ Pa, 4×10⁻¹⁰ Pa, 5×10⁻¹⁰ Pa, 6×10⁻¹⁰ Pa, 7×10⁻¹⁰ Pa, 8×10⁻¹⁰ Pa, 9×10⁻¹⁰ Pa, 10⁻⁹ Pa, 2×10⁻⁹ Pa, 3×10⁻⁹ Pa, 4×10⁻⁹ Pa, 5×10⁻⁹ Pa, 6×10⁻⁹ Pa, 7×10⁻⁹ Pa, 8×10⁻⁹ Pa, 9×10⁻⁹ Pa, 10⁻⁸ Pa, 2×10⁻⁸ Pa, 3×10⁻⁸ Pa, 4×10⁻⁸ Pa, 5×10⁻⁸ Pa, 6×10⁻⁸ Pa, 7×10⁻⁸ Pa, 8×10⁻⁸ Pa, 9×10⁻⁸ Pa, 10⁻⁷ Pa, 2×10⁻⁷ Pa, 3×10⁻⁷ Pa, 4×10⁻⁷ Pa, 5×10⁻⁷ Pa, 6×10⁻⁷ Pa, 7×10⁻⁷ Pa, 8×10⁻⁷ Pa, 9×10⁻⁷ Pa, 10⁻⁶ Pa, or higher. The vacuum units may be configured to maintain the system 200 at a pressure that is within a range defined by any two of the preceding values.

The system 200 may comprise one or more state preparation units 250. The state preparation units may comprise any state preparation unit described herein, such as a state preparation unit described herein with respect to FIG. 5. The state preparation units may be configured to prepare a state of the plurality of atoms.

The system 200 may comprise one or more atom reservoirs 260. The atom reservoirs may be configured to supply one or more replacement atoms to replace one or more atoms at one or more optical trapping sites upon loss of the atoms from the optical trapping sites. The atom reservoirs may be spatially separated from the optical trapping units. For instance, the atom reservoirs may be located at a distance from the optical trapping units.

Alternatively or in addition, the atom reservoirs may comprise a portion of the optical trapping sites of the optical trapping units. A first subset of the optical trapping sites may be utilized for performing quantum computations and may be referred to as a set of computationally-active optical trapping sites, while a second subset of the optical trapping sites may serve as an atom reservoir. For instance, the first subset of optical trapping sites may comprise an interior array of optical trapping sites, while the second subset of optical trapping sites comprises an exterior array of optical trapping sites surrounding the interior array. The interior array may comprise a rectangular, square, rectangular prism, or cubic array of optical trapping sites.

The system 200 may comprise one or more atom movement units 270. The atom movement units may be configured to move the one or more replacement atoms from the one or more atoms reservoirs to the one or more optical trapping sites. For instance, the one or more atom movement units may comprise one or more electrically tunable lenses, acousto-optic deflectors (AODs), or spatial light modulators (SLMs).

The system 200 may comprise one or more entanglement units 280. The entanglement units may be configured to quantum mechanically entangle at least a first atom of the plurality of atoms with at least a second atom of the plurality of atoms. The first or second atom may be in a superposition state at the time of quantum mechanical entanglement. Alternatively or in addition, the first or second atom may not be in a superposition state at the time of quantum mechanical entanglement. The first atom and the second atom may be quantum mechanically entangled through one or more magnetic dipole interactions, induced magnetic dipole interactions, electric dipole interactions, or induced electric dipole interactions. The entanglement units may be configured to quantum mechanically entangle any number of atoms described herein.

The entanglement units may also be configured to quantum mechanically entangle at least a subset of the atoms with at least another atom to form one or more multi-qubit units. The multi-qubit units may comprise two-qubit units, three-qubit units, four-qubit units, or n-qubit units, where n may be 5, 6, 7, 8, 9, 10, or more. For instance, a two-qubit unit may comprise a first atom quantum mechanically entangled with a second atom, a three-qubit unit may comprise a first atom quantum mechanically entangled with a second and third atom, a four-qubit unit may comprise a first atom quantum mechanically entangled with a second, third, and fourth atom, and so forth. The first, second, third, or fourth atom may be in a superposition state at the time of quantum mechanical entanglement. Alternatively or in addition, the first, second, third, or fourth atom may not be in a superposition state at the time of quantum mechanical entanglement. The first, second, third, and fourth atom may be quantum mechanically entangled through one or more magnetic dipole interactions, induced magnetic dipole interactions, electric dipole interactions, or induced electric dipole interactions.

The entanglement units may comprise one or more Rydberg units. The Rydberg units may be configured to electronically excite the at least first atom to a Rydberg state or to a superposition of a Rydberg state and a lower-energy atomic state, thereby forming one or more Rydberg atoms or dressed Rydberg atoms. The Rydberg units may be configured to induce one or more quantum mechanical entanglements between the Rydberg atoms or dressed Rydberg atoms and the at least second atom. The second atom may be located at a distance of at least about 200 nanometers (nm), 300 nm, 400 nm, 500 nm, 600 nm, 700 nm, 800 nm, 900 nm, 1 micrometer (μm), 2 μm, 3 μm, 4 μm, 5 μm, 6 μm, 7 μm, 8 μm, 9 μm, 10 μm, or more from the Rydberg atoms or dressed Rydberg atoms. The second atom may be located at a distance of at most about 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, or less from the Rydberg atoms or dressed Rydberg atoms. The second atom may be located at a distance from the Rydberg atoms or dressed Rydberg atoms that is within a range defined by any two of the preceding values. The Rydberg units may be configured to allow the Rydberg atoms or dressed Rydberg atoms to relax to a lower-energy atomic state, thereby forming one or more two-qubit units. The Rydberg units may be configured to induce the Rydberg atoms or dressed Rydberg atoms to relax to a lower-energy atomic state. The Rydberg units may be configured to drive the Rydberg atoms or dressed Rydberg atoms to a lower-energy atomic state. For instance, the Rydberg units may be configured to apply electromagnetic radiation (such as RF radiation or optical radiation) to drive the Rydberg atoms or dressed Rydberg atoms to a lower-energy atomic state. The Rydberg units may be configured to induce any number of quantum mechanical entanglements between any number of atoms of the plurality of atoms.

The Rydberg units may comprise one or more light sources (such as any light source described herein) configured to emit light having one or more ultraviolet (UV) wavelengths. The UV wavelengths may be selected to correspond to a wavelength that forms the Rydberg atoms or dressed Rydberg atoms. For instance, the light may comprise one or more wavelengths of at least about 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, or more. The light may comprise one or more wavelengths of at most about 400 nm, 390 nm, 380 nm, 370 nm, 360 nm, 350 nm, 340 nm, 330 nm, 320 nm, 310 nm, 300 nm, 290 nm, 280 nm, 270 nm, 260 nm, 250 nm, 240 nm, 230 nm, 220 nm, 210 nm, 200 nm, or less. The light may comprise one or more wavelengths that are within a range defined by any two of the preceding values. For instance, the light may comprise one or more wavelengths that are within a range from 300 nm to 400 nm.

The Rydberg units may be configured to induce a two-photon transition to generate an entanglement. The Rydberg units may be configured to induce a two-photon transition to generate an entanglement between two atoms. The Rydberg units may be configured to selectively induce a two-photon transition to selectively generate an entanglement between two atoms. For instance, the Rydberg units may be configured to direct electromagnetic energy (such as optical energy) to particular optical trapping sites to selectively induce a two-photon transition to selectively generate the entanglement between the two atoms. The two atoms may be trapped in nearby optical trapping sites. For instance, the two atoms may be trapped in adjacent optical trapping sites. The two-photon transition may be induced using first and second light from first and second light sources, respectively. The first and second light sources may each comprise any light source described herein (such as any laser described herein). The first light source may be the same or similar to a light source used to perform a single-qubit operation described herein. Alternatively, different light sources may be used to perform a single-qubit operation and to induce a two-photon transition to generate an entanglement. The first light source may emit light comprising one or more wavelengths in the visible region of the optical spectrum (e.g., within a range from 400 nm to 800 nm or from 650 nm to 700 nm). The second light source may emit light comprising one or more wavelengths in the ultraviolet region of the optical spectrum (e.g., within a range from 200 nm to 400 nm or from 300 nm to 350 nm). The first and second light sources may emit light having substantially equal and opposite spatially-dependent frequency shifts.

The Rydberg atoms or dressed Rydberg atoms may comprise a Rydberg state that may have sufficiently strong interatomic interactions with nearby atoms (such as nearby atoms trapped in nearby optical trapping sites) to enable the implementation of multi-qubit operations. The Rydberg states may comprise a principal quantum number of at least about 50, 60, 70, 80, 90, 100, or more. The Rydberg states may comprise a principal quantum number of at most about 100, 90, 80, 70, 60, 50, or less. The Rydberg states may comprise a principal quantum number that is within a range defined by any two of the preceding values. The Rydberg states may interact with nearby atoms through van der Waals interactions. The van der Waals interactions may shift atomic energy levels of the atoms.

State selective excitation of atoms to Rydberg levels may enable the implementation of multi-qubit operations. The multi-qubit operations may comprise two-qubit operations, three-qubit operations, or n-qubit operations, where n is 4, 5, 6, 7, 8, 9, 10, or more. Two-photon transitions may be used to excite atoms from a ground state (such as a ¹S₀ ground state) to a Rydberg state (such as an n³S₁ state, wherein n is a principal quantum number described herein).

State selectivity may be accomplished by a combination of laser polarization and spectral selectivity. The two-photon transitions may be implemented using first and second laser sources, as described herein. The first laser source may emit pi-polarized light, which may not change the projection of atomic angular momentum along a magnetic field. The second laser may emit circularly polarized light, which may change the projection of atomic angular momentum along the magnetic field by one unit. The first and second qubit levels may be excited to Rydberg level using this polarization. However, the Rydberg levels may be more sensitive to magnetic fields than the ground state so that large splittings (for instance, on the order of 100s of MHz) may be readily obtained. This spectral selectivity may allow state selective excitation to Rydberg levels.

Multi-qubit operations (such as two-qubit operations, three-qubit operations, four-qubit operations, and so forth) may rely on energy shifts of levels due to van der Waals interactions described herein. Such shifts may either prevent the excitation of one atom conditional on the state of the other or change the coherent dynamics of excitation of the two-atom system to enact a two-qubit operation. In some cases, “dressed states” may be generated under continuous driving to enact two-qubit operations without requiring full excitation to a Rydberg level (for instance, as described in www.arxiv.org/abs/1605.05207, which is incorporated herein by reference in its entirety for all purposes).

The system 200 may comprise one or more second electromagnetic delivery units (not shown in FIG. 2). The second electromagnetic delivery units may comprise any electromagnetic delivery unit described herein, such as an electromagnetic delivery unit described herein with respect to FIG. 4. The first and second electromagnetic delivery units may be the same. The first and second electromagnetic delivery units may be different. The second electromagnetic delivery units may be configured to apply second electromagnetic energy to the one or more multi-qubit units. The second electromagnetic energy may comprise one or more pulse sequences. The first electromagnetic energy may precede, be simultaneous with, or follow the second electromagnetic energy.

The pulse sequences may comprise any number of pulses. For instance, the pulse sequences may comprise at least about 1, 2, 3, 4, 5, 6, 7, 8, 9, 10, 20, 30, 40, 50, 60, 70, 80, 90, 100, 200, 300, 400, 500, 600, 700, 800, 900, 1,000, or more pulses. The pulse sequences may comprise at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 pulses. The pulse sequences may comprise a number of pulses that is within a range defined by any two of the preceding values. Each pulse of the pulse sequence may comprise any pulse shape, such as any pulse shape described herein.

The pulse sequences may be configured to decrease the duration of time required to implement multi-qubit operations, as described herein (for instance, with respect to Example 3). For instance, the pulse sequences may comprise a duration of at least about 10 nanoseconds (ns), 20 ns, 30 ns, 40 ns, 50 ns, 60 ns, 70 ns, 80 ns, 90 ns, 100 ns, 200 ns, 300 ns, 400 ns, 500 ns, 600 ns, 700 ns, 800 ns, 900 ns, 1 microsecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, or more. The pulse sequences may comprise a duration of at most about 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, or less. The pulse sequences may comprise a duration that is within a range defined by any two of the preceding values.

The pulse sequences may be configured to increase the fidelity of multi-qubit operations, as described herein. For instance, the pulse sequences may enable multi-qubit operations with a fidelity of at least about 0.5, 0.6, 0.7, 0.8, 0.9, 0.91, 0.92, 0.93, 0.94, 0.95, 0.96, 0.97, 0.98, 0.99, 0.991, 0.992, 0.993, 0.994, 0.995, 0.996, 0.997, 0.998, 0.999, 0.9991, 0.9992, 0.9993, 0.9994, 0.9995, 0.9996, 0.9997, 0.9998, 0.9999, 0.99991, 0.99992, 0.99993, 0.99994, 0.99995, 0.99996, 0.99997, 0.99998, 0.99999, 0.999991, 0.999992, 0.999993, 0.999994, 0.999995, 0.999996, 0.999997, 0.999998, 0.999999, or more. The pulse sequences may enable multi-qubit operations with a fidelity of at most about 0.999999, 0.999998, 0.999997, 0.999996, 0.999995, 0.999994, 0.999993, 0.999992, 0.999991, 0.99999, 0.99998, 0.99997, 0.99996, 0.99995, 0.99994, 0.99993, 0.99992, 0.99991, 0.9999, 0.9998, 0.9997, 0.9996, 0.9995, 0.9994, 0.9993, 0.9992, 0.9991, 0.999, 0.998, 0.997, 0.996, 0.995, 0.994, 0.993, 0.992, 0.991, 0.99, 0.98, 0.97, 0.96, 0.95, 0.94, 0.93, 0.92, 0.91, 0.9, 0.8, 0.7, 0.6, 0.5, or less. The pulse sequences may enable multi-qubit operations with a fidelity that is within a range defined by any two of the preceding values.

The pulse sequences may enable the implementation of multi-qubit operations on non-adiabatic timescales while maintaining effectively adiabatic dynamics. For instance, the pulse sequences may comprise one or more of shortcut to adiabaticity (STA) pulse sequences, transitionless quantum driving (TQD) pulse sequences, superadiabatic pulse sequences, counterdiabatic driving pulse sequences, derivative removal by adiabatic gate (DRAG) pulse sequences, and weak anharmonicity with average Hamiltonian (Wah Wah) pulse sequences. For instance, the pulse sequences may be similar to those described in M. V. Berry, “Transitionless Quantum Driving,” Journal of Physics A: Mathematical and Theoretical 42(36), 365303 (2009), www.doi.org/10.1088/1751-8113/42/36/365303; Y.-Y. Jau et al., “Entangling Atomic Spins with a Strong Rydberg-Dressed Interaction,” Nature Physics 12(1), 71-74 (2016); T. Keating et al., “Robust Quantum Logic in Neutral Atoms via Adiabatic Rydberg Dressing,” Physical Review A 91, 012337 (2015); A. Mitra et al., “Robust Mölmer-Sorenson Gate for Neutral Atoms Using Rapid Adiabatic Rydberg Dressing,” www.arxiv.org/abs/1911.04045 (2019); or L. S. Theis et al., “Counteracting Systems of Diabaticities Using DRAG Controls: The Status after 10 Years,” Europhysics Letters 123(6), 60001 (2018), each of which is incorporated herein by reference in its entirety for all purposes.

The pulse sequences may further comprise one or more optimal control pulse sequences. The optimal control pulse sequences may be derived from one or more procedures, including gradient ascent pulse engineering (GRAPE) methods, Krotov's method, chopped basis methods, chopped random basis (CRAB) methods, Nelder-Mead methods, gradient optimization using parametrization (GROUP) methods, genetic algorithm methods, and gradient optimization of analytic controls (GOAT) methods. For instance, the pulse sequences may be similar to those described in N. Khaneja et al., “Optimal Control of Coupled Spin Dynamics: Design of NMR Pulse Sequences by Gradient Ascent Algorithms,” Journal of Magnetic Resonance 172(2), 296-305 (2005); or J. T. Merrill et al., “Progress in Compensating Pulse Sequences for Quantum Computation,” Advances in Chemical Physics 154, 241-294 (2014), each of which is incorporated by reference in its entirety for all purposes.

### Example of Cloud Computing

The system 200 may be operatively coupled to a digital computer described herein (such as a digital computer described herein with respect to FIG. 1) over a network described herein (such as a network described herein with respect to FIG. 1). The network may comprise a cloud computing network.

### Example of Optical Trapping Units

FIG. 3A shows an example of an optical trapping unit 210. The optical trapping unit may be configured to generate a plurality 211 of spatially distinct optical trapping sites, as described herein. For instance, as shown in FIG. 3B, the optical trapping unit may be configured to generate a first optical trapping site 211a, second optical trapping site 211b, third optical trapping site 211c, fourth optical trapping site 211d, fifth optical trapping site 211e, sixth optical trapping site 211f, seventh optical trapping site 211g, eighth optical trapping site 211h, and ninth optical trapping site 211i, as depicted in FIG. 3A. The plurality of spatially distinct optical trapping sites may be configured to trap a plurality of atoms, such as first atom 212a, second atom 212b, third atom 212c, and fourth atom 212d, as depicted in FIG. 3A. As depicted in FIG. 3B, each optical trapping site may be configured to trap a single atom. As depicted in FIG. 3B, some of the optical trapping sites may be empty (i.e., not trap an atom).

As shown in FIG. 3B, the plurality of optical trapping sites may comprise a two-dimensional (2D) array. The 2D array may be perpendicular to the optical axis of optical components of the optical trapping unit depicted in FIG. 3A. Alternatively, the plurality of optical trapping sites may comprise a one-dimensional (1D) array or a three-dimensional (3D) array.

Although depicted as comprising nine optical trapping sites filled by four atoms in FIG. 3B, the optical trapping unit 210 may be configured to generate any number of spatially distinct optical trapping sites described herein and may be configured to trap any number of atoms described herein.

Each optical trapping site of the plurality of optical trapping sites may be spatially separated from each other optical trapping site by a distance of at least about 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, or more. Each optical trapping site may be spatially separated from each other optical trapping site by a distance of at most about 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, or less. Each optical trapping site maybe spatially separated from each other optical trapping site by a distance that is within a range defined by any two of the preceding values.

The optical trapping sites may comprise one or more optical tweezers. Optical tweezers may comprise one or more focused laser beams to provide an attractive or repulsive force to hold or move the one or more atoms. The beam waist of the focused laser beams may comprise a strong electric field gradient. The atoms may be attracted or repelled along the electric field gradient to the center of the laser beam, which may contain the strongest electric field. The optical trapping sites may comprise one or more optical lattice sites of one or more optical lattices. The optical trapping sites may comprise one or more optical lattice sites of one or more one-dimensional (1D) optical lattices, two-dimensional (2D) optical lattices, or three-dimensional (3D) optical lattices. For instance, the optical trapping sites may comprise one or more optical lattice sites of a 2D optical lattice, as depicted in FIG. 3B.

The optical lattices may be generated by interfering counter-propagating light (such as counter-propagating laser light) to generate a standing wave pattern having a periodic succession of intensity minima and maxima along a particular direction. A 1D optical lattice may be generated by interfering a single pair of counter-propagating light beams. A 2D optical lattice may be generated by interfering two pairs of counter-propagating light beams. A 3D optical lattice may be generated by interfering three pairs of counter-propagating lights beams. The light beams may be generated by different light sources or by the same light source. Therefore, an optical lattice may be generated by at least about 1, 2, 3, 4, 5, 6, or more light sources or at most about 6, 5, 4, 3, 2, or 1 light sources.

Returning to the description of FIG. 3A, the optical trapping unit may comprise one or more light sources configured to emit light to generate the plurality of optical trapping sites as described herein. For instance, the optical trapping unit may comprise a single light source 213, as depicted in FIG. 3A. Though depicted as comprising a single light source in FIG. 3A, the optical trapping unit may comprise any number of light sources, such as at least about 1, 2, 3, 4, 5, 6, 7, 8, 9, 10, or more light sources or at most about 10, 9, 8, 7, 6, 5, 4, 3, 2, or 1 light sources. The light sources may comprise one or more lasers. The lasers may be configured to operate at a resolution limit of the lasers. For example, the lasers can be configured to provide diffraction limited spot sizes for optical trapping.

The lasers may comprise one or more continuous wave lasers. The lasers may comprise one or more pulsed lasers. The lasers may comprise one or more gas lasers, such as one or more helium-neon (HeNe) lasers, argon (Ar) lasers, krypton (Kr) lasers, xenon (Xe) ion lasers, nitrogen (N₂) lasers, carbon dioxide (CO₂) lasers, carbon monoxide (CO) lasers, transversely excited atmospheric (TEA) lasers, or excimer lasers. For instance, the lasers may comprise one or more argon dimer (Ar₂) excimer lasers, krypton dimer (Kr₂) excimer lasers, fluorine dimer (F₂) excimer lasers, xenon dimer (Xe₂) excimer lasers, argon fluoride (ArF) excimer lasers, krypton chloride (KrCl) excimer lasers, krypton fluoride (KrF) excimer lasers, xenon bromide (XeBr) excimer lasers, xenon chloride (XeCl) excimer lasers, or xenon fluoride (XeF) excimer lasers. The laser may comprise one or more dye lasers.

The lasers may comprise one or more metal-vapor lasers, such as one or more helium-cadmium (HeCd) metal-vapor lasers, helium-mercury (HeHg) metal-vapor lasers, helium-selenium (HeSe) metal-vapor lasers, helium-silver (HeAg) metal-vapor lasers, strontium (Sr) metal-vapor lasers, neon-copper (NeCu) metal-vapor lasers, copper (Cu) metal-vapor lasers, gold (Au) metal-vapor lasers, manganese (Mn) metal-vapor laser, or manganese chloride (MnCl₂) metal-vapor lasers.

The lasers may comprise one or more solid-state lasers, such as one or more ruby lasers, metal-doped crystal lasers, or metal-doped fiber lasers. For instance, the lasers may comprise one or more neodymium-doped yttrium aluminum garnet (Nd:YAG) lasers, neodymium/chromium doped yttrium aluminum garnet (Nd/Cr:YAG) lasers, erbium-doped yttrium aluminum garnet (Er:YAG) lasers, neodymium-doped yttrium lithium fluoride (Nd:YLF) lasers, neodymium-doped yttrium orthovanadate (ND:YVO₄) lasers, neodymium-doped yttrium calcium oxoborate (Nd:YCOB) lasers, neodymium glass (Nd:glass) lasers, titanium sapphire (Ti:sapphire) lasers, thulium-doped yttrium aluminum garnet (Tm:YAG) lasers, ytterbium-doped yttrium aluminum garnet (Yb:YAG) lasers, ytterbium-doped glass (Yt:glass) lasers, holmium yttrium aluminum garnet (Ho:YAG) lasers, chromium-doped zinc selenide (Cr:ZnSe) lasers, cerium-doped lithium strontium aluminum fluoride (Ce:LiSAF) lasers, cerium-doped lithium calcium aluminum fluoride (Ce:LiCAF) lasers, erbium-doped glass (Er:glass) lasers, erbium-ytterbium-codoped glass (Er/Yt:glass) lasers, uranium-doped calcium fluoride (U:CaF₂) lasers, or samarium-doped calcium fluoride (Sm:CaF₂) lasers.

The lasers may comprise one or more semiconductor lasers or diode lasers, such as one or more gallium nitride (GaN) lasers, indium gallium nitride (InGaN) lasers, aluminum gallium indium phosphide (AlGaInP) lasers, aluminum gallium arsenide (AlGaAs) lasers, indium gallium arsenic phosphide (InGaAsP) lasers, vertical cavity surface emitting lasers (VCSELs), or quantum cascade lasers.

The lasers may emit continuous wave laser light. The lasers may emit pulsed laser light. The lasers may have a pulse length of at least about 1 femtoseconds (fs), 2 fs, 3 fs, 4 fs, 5 fs, 6 fs, 7 fs, 8 fs, 9 fs, 10 fs, 20 fs, 30 fs, 40 fs, 50 fs, 60 fs, 70 fs, 80 fs, 90 fs, 100 fs, 200 fs, 300 fs, 400 fs, 500 fs, 600 fs, 700 fs, 800 fs, 900 fs, 1 picosecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, 200 μs, 300 μs, 400 μs, 500 μs, 600 μs, 700 μs, 800 μs, 900 μs, 1 nanosecond (ns), 2 ns, 3 ns, 4 ns, 5 ns, 6 ns, 7 ns, 8 ns, 9 ns, 10 ns, 20 ns, 30 ns, 40 ns, 50 ns, 60 ns, 70 ns, 80 ns, 90 ns, 100 ns, 200 ns, 300 ns, 400 ns, 500 ns, 600 ns, 700 ns, 800 ns, 900 ns, 1,000 ns, or more. The lasers may have a pulse length of at most about 1,000 ns, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, 9 ns, 8 ns, 7 ns, 6 ns, 5 ns, 4 ns, 3 ns, 2 ns, 1 ns, 900 μs, 800 μs, 700 μs, 600 μs, 500 μs, 400 μs, 300 μs, 200 μs, 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, 900 fs, 800 fs, 700 fs, 600 fs, 500 fs, 400 fs, 300 fs, 200 fs, 100 fs, 90 fs, 80 fs, 70 fs, 60 fs, 50 fs, 40 fs, 30 fs, 20 fs, 10 fs, 9 fs, 8 fs, 7 fs, 6 fs, 5 fs, 4 fs, 3 fs, 2 fs, 1 fs, or less. The lasers may have a pulse length that is within a range defined by any two of the preceding values.

The lasers may have a repetition rate of at least about 1 hertz (Hz), 2 Hz, 3 Hz, 4 Hz, 5 Hz, 6 Hz, 7 Hz, 8 Hz, 9 Hz, 10 Hz, 20 Hz, 30 Hz, 40 Hz, 50 Hz, 60 Hz, 70 Hz, 80 Hz, 90 Hz, 100 Hz, 200 Hz, 300 Hz, 400 Hz, 500 Hz, 600 Hz, 700 Hz, 800 Hz, 900 Hz, 1 kilohertz (kHz), 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 megahertz (MHz), 2 MHz, 3 MHz, 4 MHz, 5 MHz, 6 MHz, 7 MHz, 8 MHz, 9 MHz, 10 MHz, 20 MHz, 30 MHz, 40 MHz, 50 MHz, 60 MHz, 70 MHz, 80 MHz, 90 MHz, 100 MHz, 200 MHz, 300 MHz, 400 MHz, 500 MHz, 600 MHz, 700 MHz, 800 MHz, 900 MHz, 1,000 MHz, or more. The lasers may have a repetition rate of at most about 1,000 MHz, 900 MHz, 800 MHz, 700 MHz, 600 MHz, 500 MHz, 400 MHz, 300 MHz, 200 MHz, 100 MHz, 90 MHz, 80 MHz, 70 MHz, 60 MHz, 50 MHz, 40 MHz, 30 MHz, 20 MHz, 10 MHz, 9 MHz, 8 MHz, 7 MHz, 6 MHz, 5 MHz, 4 MHz, 3 MHz, 2 MHz, 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, 900 Hz, 800 Hz, 700 Hz, 600 Hz, 500 Hz, 400 Hz, 300 Hz, 200 Hz, 100 Hz, 90 Hz, 80 Hz, 70 Hz, 60 Hz, 50 Hz, 40 Hz, 30 Hz, 20 Hz, 10 Hz, 9 Hz, 8 Hz, 7 Hz, 6 Hz, 5 Hz, 4 Hz, 3 Hz, 2 Hz, 1 Hz, or less. The lasers may have a repetition rate that is within a range defined by any two of the preceding values.

The lasers may emit light having a pulse energy of at least about 1 nanojoule (nJ), 2 nJ, 3 nJ, 4 nJ, 5 nJ, 6 nJ, 7 nJ, 8 nJ, 9 nJ, 10 nJ, 20 nJ, 30 nJ, 40 nJ, 50 nJ, 60 nJ, 70 nJ, 80 nJ, 90 nJ, 100 nJ, 200 nJ, 300 nJ, 400 nJ, 500 nJ, 600 nJ, 700 nJ, 800 nJ, 900 nJ, 1 microjoule (μJ), 2 μJ, 3 μJ, 4 μJ, 5 μJ, 6 μJ, 7 μJ, 8 μJ, 9 μJ, 10 μJ, 20 μJ, 30 μJ, 40 μJ, 50 μJ, 60 μJ, 70 μJ, 80 μJ, 90 μJ, 100 μJ, 200 μJ, 300 μJ, 400 μJ, 500 μJ, 600 μJ, 700 μJ, 800 μJ, 900 μJ, a least 1 millijoule (mJ), 2 mJ, 3 mJ, 4 mJ, 5 mJ, 6 mJ, 7 mJ, 8 mJ, 9 mJ, 10 mJ, 20 mJ, 30 mJ, 40 mJ, 50 mJ, 60 mJ, 70 mJ, 80 mJ, 90 mJ, 100 mJ, 200 mJ, 300 mJ, 400 mJ, 500 mJ, 600 mJ, 700 mJ, 800 mJ, 900 mJ, a least 1 Joule (J), or more. The lasers may emit light having a pulse energy of at most about 1 J, 900 mJ, 800 mJ, 700 mJ, 600 mJ, 500 mJ, 400 mJ, 300 mJ, 200 mJ, 100 mJ, 90 mJ, 80 mJ, 70 mJ, 60 mJ, 50 mJ, 40 mJ, 30 mJ, 20 mJ, 10 mJ, 9 mJ, 8 mJ, 7 mJ, 6 mJ, 5 mJ, 4 mJ, 3 mJ, 2 mJ, 1 mJ, 900 μJ, 800 μJ, 700 μJ, 600 μJ, 500 μJ, 400 μJ, 300 μJ, 200 μJ, 100 μJ, 90 μJ, 80 μJ, 70 μJ, 60 μJ, 50 μJ, 40 μJ, 30 μJ, 20 μJ, 10 μJ, 9 μJ, 8 μJ, 7 μJ, 6 μJ, 5 μJ, 4 μJ, 3 μJ, 2 μJ, 1 μJ, 900 nJ, 800 nJ, 700 nJ, 600 nJ, 500 nJ, 400 nJ, 300 nJ, 200 nJ, 100 nJ, 90 nJ, 80 nJ, 70 nJ, 60 nJ, 50 nJ, 40 nJ, 30 nJ, 20 nJ, 10 nJ, 9 nJ, 8 nJ, 7 nJ, 6 nJ, 5 nJ, 4 nJ, 3 nJ, 2 nJ, 1 nJ, or less. The lasers may emit light having a pulse energy that is within a range defined by any two of the preceding values.

The lasers may emit light having an average power of at least about 1 microwatt (μW), 2 μW, 3 μW, 4 μW, 5 μW, 6 μW, 7 μW, 8 μW, 9 μW, 10 μW, 20 μW, 30 μW, 40 μW, 50 μW, 60 μW, 70 μW, 80 μW, 90 μW, 100 μW, 200 μW, 300 μW, 400 μW, 500 μW, 600 μW, 700 μW, 800 μW, 900 μW, 1 milliwatt (mW), 2 mW, 3 mW, 4 mW, 5 mW, 6 mW, 7 mW, 8 mW, 9 mW, 10 mW, 20 mW, 30 mW, 40 mW, 50 mW, 60 mW, 70 mW, 80 mW, 90 mW, 100 mW, 200 mW, 300 mW, 400 mW, 500 mW, 600 mW, 700 mW, 800 mW, 900 mW, 1 watt (W), 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1,000 W, or more. The lasers may emit light having an average power of at most about 1,000 W, 900 W, 800 W, 700 W, 600 W, 500 W, 400 W, 300 W, 200 W, 100 W, 90 W, 80 W, 70 W, 60 W, 50 W, 40 W, 30 W, 20 W, 10 W, 9 W, 8 W, 7 W, 6 W, 5 W, 4 W, 3 W, 2 W, 1 W, 900 mW, 800 mW, 700 mW, 600 mW, 500 mW, 400 mW, 300 mW, 200 mW, 100 mW, 90 mW, 80 mW, 70 mW, 60 mW, 50 mW, 40 mW, 30 mW, 20 mW, 10 mW, 9 mW, 8 mW, 7 mW, 6 mW, 5 mW, 4 mW, 3 mW, 2 mW, 1 mW, 900 μW, 800 μW, 700 μW, 600 μW, 500 μW, 400 μW, 300 μW, 200 μW, 100 μW, 90 μW, 80 μW, 70 μW, 60 μW, 50 μW, 40 μW, 30 μW, 20 μW, 10 μW, 9 μW, 8 μW, 7 μW, 6 μW, 5 μW, 4 μW, 3 μW, 2 μW, 1 μW, or more. The lasers may emit light having a power that is within a range defined by any two of the preceding values.

The lasers may emit light comprising one or more wavelengths in the ultraviolet (UV), visible, or infrared (IR) portions of the electromagnetic spectrum. The lasers may emit light comprising one or more wavelengths of at least about 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, 1,010 nm, 1,020 nm, 1,030 nm, 1,040 nm, 1,050 nm, 1,060 nm, 1,070 nm, 1,080 nm, 1,090 nm, 1,100 nm, 1,110 nm, 1,120 nm, 1,130 nm, 1,140 nm, 1,150 nm, 1,160 nm, 1,170 nm, 1,180 nm, 1,190 nm, 1,200 nm, 1,210 nm, 1,220 nm, 1,230 nm, 1,240 nm, 1,250 nm, 1,260 nm, 1,270 nm, 1,280 nm, 1,290 nm, 1,300 nm, 1,310 nm, 1,320 nm, 1,330 nm, 1,340 nm, 1,350 nm, 1,360 nm, 1,370 nm, 1,380 nm, 1,390 nm, 1,400 nm, or more. The lasers may emit light comprising one or more wavelengths of at most about 1,400 nm, 1,390 nm, 1,380 nm, 1,370 n, 1,360 nm, 1,350 nm, 1,340 nm, 1,330 nm, 1,320 nm, 1,310 nm, 1,300 nm, 1,290 nm, 1,280 nm, 1,270 n, 1,260 nm, 1,250 nm, 1,240 nm, 1,230 nm, 1,220 nm, 1,210 nm, 1,200 nm, 1,190 nm, 1,180 nm, 1,170 n, 1,160 nm, 1,150 nm, 1,140 nm, 1,130 nm, 1,120 nm, 1,110 nm, 1,100 nm, 1,090 nm, 1,080 nm, 1,070 n, 1,060 nm, 1,050 nm, 1,040 nm, 1,030 nm, 1,020 nm, 1,010 nm, 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, 390 nm, 380 nm, 370 nm, 360 nm, 350 nm, 340 nm, 330 nm, 320 nm, 310 nm, 300 nm, 290 nm, 280 nm, 270 nm, 260 nm, 250 nm, 240 nm, 230 nm, 220 nm, 210 nm, 200 nm. The lasers may emit light comprising one or more wavelengths that are within a range defined by any two of the preceding values.

The lasers may emit light having a bandwidth of at least about 1×10⁻¹⁵ nm, 2×10⁻¹⁵ nm, 3×10⁻¹⁵ nm, 4×10⁻¹⁵ nm, 5×10⁻¹⁵ nm, 6×10⁻¹⁵ nm, 7×10⁻¹⁵ nm, 8×10⁻¹⁵ nm, 9×10⁻¹⁵ nm, 1×10⁻¹⁴ nm, 2×10⁻¹⁴ nm, 3×10⁻¹⁴ nm, 4×10⁻¹⁴ nm, 5×10⁻¹⁴ nm, 6×10⁻¹⁴ nm, 7×10⁻¹⁴ nm, 8×10⁻¹⁴ nm, 9×10⁻¹⁴ nm, 1×10⁻¹³ nm, 2×10⁻¹³ nm, 3×10⁻¹³ nm, 4×10⁻¹³ nm, 5×10⁻¹³ nm, 6×10⁻¹³ nm, 7×10⁻¹³ nm, 8×10⁻¹³ nm, 9×10⁻¹³ nm, 1×10⁻¹² nm, 2×10⁻¹² nm, 3×10⁻¹² nm, 4×10⁻¹² nm, 5×10⁻¹² nm, 6×10⁻¹² nm, 7×10⁻¹² nm, 8×10⁻¹² nm, 9×10⁻¹² nm, 1×10⁻¹¹ nm, 2×10⁻¹¹ nm, 3×10⁻¹¹ nm, 4×10⁻¹¹ nm, 5×10⁻¹¹ nm, 6×10⁻¹¹ nm, 7×10⁻¹¹ nm, 8×10⁻¹¹ nm, 9×10⁻¹¹ nm, 1×10⁻¹⁰ nm, 2×10⁻¹⁰ nm, 3×10⁻¹⁰ nm, 4×10⁻¹⁰ nm, 5×10⁻¹⁰ nm, 6×10⁻¹⁰ nm, 7×10⁻¹⁰ nm, 8×10⁻¹⁰ nm, 9×10⁻¹⁰ nm, 1×10⁻⁹ nm, 2×10⁻⁹ nm, 3×10⁻⁹ nm, 4×10⁻⁹ nm, 5×10⁻⁹ nm, 6×10⁻⁹ nm, 7×10⁻⁹ nm, 8×10⁻⁹ nm, 9×10⁻⁹ nm, 1×10⁻⁸ nm, 2×10⁻⁸ nm, 3×10⁻⁸ nm, 4×10⁻⁸ nm, 5×10⁻⁸ nm, 6×10⁻⁸ nm, 7×10⁻⁸ nm, 8×10⁻⁸ nm, 9×10⁻⁸ nm, 1×10⁻⁷ nm, 2×10⁻⁷ nm, 3×10⁻⁷ nm, 4×10⁻⁷ nm, 5×10⁻⁷ nm, 6×10⁻⁷ nm, 7×10⁻⁷ nm, 8×10⁻⁷ nm, 9×10⁻⁷ nm, 1×10⁻⁶ nm, 2×10⁻⁶ nm, 3×10⁻⁶ nm, 4×10⁻⁶ nm, 5×10⁻⁶ nm, 6×10⁻⁶ nm, 7×10⁻⁶ nm, 8×10⁻⁶ nm, 9×10⁻⁶ nm, 1×10⁻⁵ nm, 2×10⁻⁵ nm, 3×10⁻⁵ nm, 4×10⁻⁵ nm, 5×10⁻⁵ nm, 6×10⁻⁵ nm, 7×10⁻⁵ nm, 8×10⁻⁵ nm, 9×10⁻⁵ nm, 1×10⁻⁴ nm, 2×10⁻⁴ nm, 3×10⁻⁴ nm, 4×10⁻⁴ nm, 5×10⁻⁴ nm, 6×10⁻⁴ nm, 7×10⁻⁴ nm, 8×10⁻⁴ nm, 9×10⁻⁴ nm, 1×10⁻³ nm, or more. The lasers may emit light having a bandwidth of at most about 1×10⁻³ nm, 9×10⁻⁴ nm, 8×10⁻⁴ nm, 7×10⁻⁴ nm, 6×10⁻⁴ nm, 5×10⁻⁴ nm, 4×10⁻⁴ nm, 3×10⁻⁴ nm, 2×10⁻⁴ nm, 1×10⁻⁴ nm, 9×10⁻⁵ nm, 8×10⁻⁵ nm, 7×10⁻⁵ nm, 6×10⁻⁵ nm, 5×10⁻⁵ nm, 4×10⁻⁵ nm, 3×10⁻⁵ nm, 2×10⁻⁵ nm, 1×10⁻⁵ nm, 9×10⁻⁶ nm, 8×10⁻⁶ nm, 7×10⁻⁶ nm, 6×10⁻⁶ nm, 5×10⁻⁶ nm, 4×10⁻⁶ nm, 3×10⁻⁶ nm, 2×10⁻⁶ nm, 1×10⁻⁶ nm, 9×10⁻⁷ nm, 8×10⁻⁷ nm, 7×10⁻⁷ nm, 6×10⁻⁷ nm, 5×10⁻⁷ nm, 4×10⁻⁷ nm, 3×10⁻⁷ nm, 2×10⁻⁷ nm, 1×10⁻⁷ nm, 9×10⁻⁸ nm, 8×10⁻⁸ nm, 7×10⁻⁸ nm, 6×10⁻⁸ nm, 5×10⁻⁸ nm, 4×10⁻⁸ nm, 3×10⁻⁸ nm, 2×10⁻⁸ nm, 1×10⁻⁸ nm, 9×10⁻⁹ nm, 8×10⁻⁹ nm, 7×10⁻⁹ nm, 6×10⁻⁹ nm, 5×10⁻⁹ nm, 4×10⁻⁹ nm, 3×10⁻⁹ nm, 2×10⁻⁹ nm, 1×10⁻⁹ nm, 9×10⁻¹⁰ nm, 8×10⁻¹⁰ nm, 7×10⁻¹⁰ nm, 6×10⁻¹⁰ nm, 5×10⁻¹⁰ nm, 4×10⁻¹⁰ nm, 3×10⁻¹⁰ nm, 2×10⁻¹⁰ nm, 1×10⁻¹⁰ nm, 9×10⁻¹¹ nm, 8×10⁻¹¹ nm, 7×10⁻¹¹ nm, 6×10⁻¹¹ nm, 5×10⁻¹¹ nm, 4×10⁻¹¹ nm, 3×10⁻¹¹ nm, 2×10⁻¹¹ nm, 1×10⁻¹¹ nm, 9×10⁻¹² nm, 8×10⁻¹² nm, 7×10⁻¹² nm, 6×10⁻¹² nm, 5×10⁻¹² nm, 4×10⁻¹² nm, 3×10⁻¹² nm, 2×10⁻¹² nm, 1×10⁻¹² nm, 9×10⁻¹³ nm, 8×10⁻¹³ nm, 7×10⁻¹³ nm, 6×10⁻¹³ nm, 5×10⁻¹³ nm, 4×10⁻¹³ nm, 3×10⁻¹³ nm, 2×10⁻¹³ nm, 1×10⁻¹³ nm, 9×10⁻¹⁴ nm, 8×10⁻¹⁴ nm, 7×10⁻¹⁴ nm, 6×10⁻¹⁴ nm, 5×10⁻¹⁴ nm, 4×10⁻¹⁴ nm, 3×10⁻¹⁴ nm, 2×10⁻¹⁴ nm, 1×10⁻¹⁴ nm, 9×10⁻¹⁵ nm, 8×10⁻¹⁵ nm, 7×10⁻¹⁵ nm, 6×10⁻¹⁵ nm, 5×10⁻¹⁵ nm, 4×10⁻¹⁵ nm, 3×10⁻¹⁵ nm, 2×10⁻¹⁵ nm, 1×10⁻¹⁵ nm, or less. The lasers may emit light having a bandwidth that is within a range defined by any two of the preceding values.

The light sources may be configured to emit light tuned to one or more magic wavelengths corresponding to the plurality of atoms. A magic wavelength corresponding to an atom may comprise any wavelength of light that gives rise to equal or nearly equal polarizabilities of the first and second atomic states. The magic wavelengths for a transition between the first and second atomic states may be determined by calculating the wavelength-dependent polarizabilities of the first and second atomic states and finding crossing points. Light tuned to such a magic wavelength may give rise to equal or nearly equal differential light shifts in the first and second atomic states, regardless of the intensity of the light emitted by the light sources. This may effectively decouple the first and second atomic states from motion of the atoms. The magic wavelengths may utilize one or more scalar or tensor light shifts. The scalar or tensor light shifts may depend on magnetic sublevels within the first and second atomic states.

For instance, group III atoms and metastable states of alkaline earth or alkaline earth-like atoms may possess relatively large tensor shifts whose angle relative to an applied magnetic field may be tuned to cause a situation in which scalar and tensor shifts balance and give a zero or near zero differential light shift between the first and second atomic states. The angle θ may be tuned by selecting the polarization of the emitted light. For instance, when the emitted light is linearly polarized, the total polarizability a may be written as a sum of the scalar component α_{scalar} and the tensor component αₜₑₙₛₒᵣ:

$$α = {α}_{scalar} + ( 3 cos {θ}^{2} - 1 ) {α}_{tensor}$$

By choosing θ appropriately, the polarizability of the first and second atomic states may be chosen to be equal or nearly equal, corresponding to a zero or near zero differential light shift and the motion of the atoms may be decoupled.

The light sources may be configured to direct light to one or more optical modulators (OMs) configured to generate the plurality of optical trapping sites. For instance, the optical trapping unit may comprise an OM 214 configured to generate the plurality of optical trapping sites. Although depicted as comprising one OM in FIG. 3A, the optical trapping unit may comprise any number of OMs, such as at least about 1, 2, 3, 4, 5, 6, 7, 8, 9, 10, or more OMs or at most about 10, 9, 8, 7, 6, 5, 4, 3, 2, or 1 OMs. The OMs may comprise one or more digital micromirror devices (DMDs). The OMs may comprise one or more liquid crystal devices, such as one or more liquid crystal on silicon (LCoS) devices. The OMs may comprise one or more spatial light modulators (SLMs). The OMs may comprise one or more acousto-optic deflectors (AODs) or acousto-optic modulators (AOMs). The OMs may comprise one or more electro-optic deflectors (EODs) or electro-optic modulators (EOMs).

The OM may be optically coupled to one or more optical element to generate a regular array of optical trapping sites. For instance, the OM may be optically coupled to optical element 219, as shown in FIG. 3A. The optical elements may comprise lenses or microscope objectives configured to re-direct light from the OMs to form a regular rectangular grid of optical trapping sites.

For instance, as shown in FIG. 3A, the OM may comprise an SLM, DMD, or LCoS device. The SLM, DMD, or LCoS device may be imaged onto the back focal plane of the microscope objectives. This may allow for the generation of an arbitrary configuration of optical trapping sites in two or three dimensions.

Alternatively or in addition, the OMs may comprise first and second AODs. The active regions of the first and second AODs may be imaged onto the back focal plane of the microscope objectives. The output of the first AOD may be optically coupled to the input of the second AOD. In this manner, the second AOD may make a copy of the optical output of the first AOD. This may allow for the generation of optical trapping sites in two or three dimensions.

Alternatively or in addition, the OMs may comprise static optical elements, such as one or more microlens arrays or holographic optical elements. The static optical elements may be imaged onto the back focal plane of the microscope objectives. This may allow for the generation of an arbitrary configuration of optical trapping sites in two or three dimensions.

The optical trapping unit may comprise one or more imaging units configured to obtain one or more images of a spatial configuration of the plurality of atoms trapped within the optical trapping sites. For instance, the optical trapping unit may comprise imaging unit 215. Although depicted as comprising a single imaging unit in FIG. 3A, the optical trapping unit may comprise any number of imaging units, such as at least about 1, 2, 3, 4, 5, 6, 7, 8, 9, 10, or more imaging units or at most about 10, 9, 8, 7, 6, 5, 4, 3, 2, or 1 imaging units. The imaging units may comprise one or more lens or objectives. The imaging units may comprise one or more PMTs, photodiodes, avalanche photodiodes, phototransistors, reverse-biased LEDs, CCDs, or CMOS cameras. The imaging unit may comprise one or more fluorescence detectors. The images may comprise one or more fluorescence images, single-atom fluorescence images, absorption images, single-atom absorption images, phase contrast images, or single-atom phase contrast images.

The optical trapping unit may comprise one or more spatial configuration artificial intelligence (AI) units configured to perform one or more AI operations to determine the spatial configuration of the plurality of atoms trapped within the optical trapping sites based on the images obtained by the imaging unit. For instance, the optical trapping unit may comprise spatial configuration AI unit 216. Although depicted as comprising a single spatial configuration AI unit in FIG. 3A, the optical trapping unit may comprise any number of spatial configuration AI units, such as at least about 1, 2, 3, 4, 5, 6, 7, 8, 9, 10, or more spatial configuration AI units or at most about 10, 9, 8, 7, 6, 5, 4, 3, 2, or 1 spatial configuration AI units. The AI operations may comprise any machine learning (ML) or reinforcement learning (RL) operations described herein.

The optical trapping unit may comprise one or more atom rearrangement units configured to impart an altered spatial arrangement of the plurality of atoms trapped with the optical trapping sites based on the one or more images obtained by the imaging unit. For instance, the optical trapping unit may comprise atom rearrangement unit 217. Although depicted as comprising a single atom rearrangement unit in FIG. 3A, the optical trapping unit may comprise any number of atom rearrangement units, such as at least about 1, 2, 3, 4, 5, 6, 7, 8, 9, 10, or more atom rearrangement units or at most about 10, 9, 8, 7, 6, 5, 4, 3, 2, or 1 atom rearrangement units.

The optical trapping unit may comprise one or more spatial arrangement artificial intelligence (AI) units configured to perform one or more AI operations to determine the altered spatial arrangement of the plurality of atoms trapped within the optical trapping sites based on the images obtained by the imaging unit. For instance, the optical trapping unit may comprise spatial arrangement AI unit 218. Although depicted as comprising a single spatial arrangement AI unit in FIG. 3A, the optical trapping unit may comprise any number of spatial arrangement AI units, such as at least about 1, 2, 3, 4, 5, 6, 7, 8, 9, 10, or more spatial arrangement AI units or at most about 10, 9, 8, 7, 6, 5, 4, 3, 2, or 1 spatial arrangement AI units. The AI operations may comprise any machine learning (ML) or reinforcement learning (RL) operations described herein.

In some cases, the spatial configuration AI units and the spatial arrangement AI units may be integrated into an integrated AI unit. The optical trapping unit may comprise any number of integrated AI units, such as at least about 1, 2, 3, 4, 5, 6, 7, 8, 9, 10, or more integrated AI units, or at most about 10, 9, 8, 7, 6, 5, 4, 3, 2, or 1 integrated AI units.

The atom rearrangement unit may be configured to alter the spatial arrangement in order to obtain an increase in a filling factor of the plurality of optical trapping sites. A filling factor may be defined as a ratio of the number of computationally active optical trapping sites occupied by one or more atoms to the total number of computationally active optical trapping sites available in the optical trapping unit or in a portion of the optical trapping unit. For instance, initial loading of atoms within the computationally active optical trapping sites may give rise to a filling factor of less than 100%, 90%, 80%, 70%, 60%, 50%, or less, such that atoms occupy fewer than 100%, 90%, 70%, 60%, 50%, or less of the available computationally active optical trapping sites, respectively. It may be desirable to rearrange the atoms to achieve a filling factor of at least about 50%, 60%, 70%, 80%, 90%, or 100%. By analyzing the imaging information obtained by the imaging unit, the atom rearrangement unit may attain a filling factor of at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, 99.91%, 99.92%, 99.93%, 99.94%, 99.95%, 99.96%, 99.97%, 99.98%, 99.99%, or more. The atom rearrangement unit may attain a filling factor of at most about 99.99%, 99.98%, 99.97%, 99.96%, 99.95%, 99.94%, 99.93%, 99.92%, 99.91%, 99.9%, 99.8%, 99.7%, 99.6%, 99.5%, 99.4%, 99.3%, 99.2%, 99.1%, 99%, 98%, 97%, 96%, 95%, 94%, 93%, 92%, 91%, 90%, 80%, 70%, 60%, 50%, or less. The atom rearrangement unit may attain a filling factor that is within a range defined by any two of the preceding values.

By way of example, FIG. 3C shows an example of an optical trapping unit that is partially filled with atoms. As depicted in FIG. 3C, initial loading of atoms within the optical trapping sites may give rise to a filling factor of 44.4% (4 atoms filling 9 available optical trapping sites). By moving atoms from different regions of the optical trapping unit (not shown in FIG. 3C) to unoccupied optical trapping sites or by moving atoms from an atom reservoir described herein, a much higher filling factor may be obtained, as shown in FIG. 3D.

FIG. 3D shows an example of an optical trapping unit that is completely filled with atoms. As depicted in FIG. 3D, fifth atom 212e, sixth atom 212f, seventh atom 212g, eighth atom 212h, and ninth atom 212i may be moved to fill unoccupied optical trapping sites. The fifth, sixth, seventh, eighth, and ninth atoms may be moved from different regions of the optical trapping unit (not shown in FIG. 3C) or by moving atoms from an atom reservoir described herein. Thus, the filling factor may be substantially improved following rearrangement of atoms within the optical trapping sites. For instance, a filling factor of up to 100% (such 9 atoms filling 9 available optical trapping sites, as shown in FIG. 3D) may be attained.

Atom rearrangement may be performed by (i) acquiring an image of the optical trapping unit, identifying filled and unfilled optical trapping sites, (ii) determining a set of moves to bring atoms from filled optical trapping sites to unfilled optical trapping sites, and (iii) moving the atoms from filled optical trapping sites to unfilled optical trapping sites. Operations (i), (ii), and (iii) may be performed iteratively until a large filling factor is achieved. Operation (iii) may comprise translating the moves identified in operation (ii) to waveforms that may be sent to an arbitrary waveform generator (AWG) and using the AWG to drive AODs to move the atoms. The set of moves may be determined using the Hungarian algorithm described in W. Lee et al, “Defect-Free Atomic Array Formation Using Hungarian Rearrangement Algorithm,” Physical Review A 95, 053424 (2017), which is incorporated herein by reference in its entirety for all purposes.

### Example of Electromagnetic Delivery Units

FIG. 4 shows an example of an electromagnetic delivery unit 220. The electromagnetic delivery unit may be configured to apply electromagnetic energy to one or more atoms of the plurality of atoms, as described herein. The electromagnetic delivery unit may comprise one or more light sources, such as any light source described herein. The electromagnetic energy may comprise optical energy. The optical energy may comprise any repetition rate, pulse energy, average power, wavelength, or bandwidth described herein.

The electromagnetic delivery unit may comprise one or more microwave or radio-frequency (RF) energy sources, such as one or more magnetrons, klystrons, traveling-wave tubes, gyrotrons, field-effect transistors (FETs), tunnel diodes, Gunn diodes, impact ionization avalanche transit-time (IMPATT) diodes, or masers. The electromagnetic energy may comprise microwave energy or RF energy. The RF energy may comprise one or more wavelengths of at least about 1 millimeter (mm), 2 mm, 3 mm, 4 mm, 5 mm, 6 mm, 7 mm, 8 mm, 9 mm, 10 mm, 20 mm, 30 mm, 40 mm, 50 mm, 60 mm, 70 mm, 80 mm, 90 mm, 100 mm, 200 mm, 300 mm, 400 mm, 500 mm, 600 mm, 700 mm, 800 mm, 900 mm, 1 meter (m), 2 m, 3 m, 4 m, 5 m, 6 m, 7 m, 8 m, 9 m, 10 m, 20 m, 30 m, 40 m, 50 m, 60 m, 70 m, 80 m, 90 m, 100 m, 200 m, 300 m, 400 m, 500 m, 600 m, 700 m, 800 m, 900 m, 1 kilometer (km), 2 km, 3 km, 4 km, 5 km, 6 km, 7 km, 8 km, 9 km, 10 km, or more. The RF energy may comprise one or more wavelengths of at most about 10 km, 9 km, 8 km, 7 km, 6 km, 5 km, 4 km, 3 km, 2 km, 1 km, 900 m, 800 m, 700 m, 600 m, 500 m, 400 m, 300 m, 200 m, 100 m, 90 m, 80 m, 70 m, 60 m, 50 m, 40 m, 30 m, 20 m, 10 m, 9 m, 8 m, 7 m, 6 m, 5 m, 4 m, 3 m, 2 m, 1 m, 900 mm, 800 mm, 700 mm, 600 mm, 500 mm, 400 mm, 300 mm, 200 mm, 100 mm, 90 mm, 80 mm, 70 mm, 60 mm, 50 mm, 40 mm, 30 mm, 20 mm, 10 mm, 9 mm, 8 mm, 7 mm, 6 mm, 5 mm, 4 mm, 3 mm, 2 mm, 1 mm, or less. The RF energy may comprise one or more wavelengths that are within a range defined by any two of the preceding values.

The RF energy may comprise an average power of at least about 1 microwatt (μW), 2 μW, 3 μW, 4 μW, 5 μW, 6 μW, 7 μW, 8 μW, 9 μW, 10 μW, 20 μW, 30 μW, 40 μW, 50 μW, 60 μW, 70 μW, 80 μW, 90 μW, 100 μW, 200 μW, 300 μW, 400 μW, 500 μW, 600 μW, 700 μW, 800 μW, 900 μW, 1 milliwatt (mW), 2 mW, 3 mW, 4 mW, 5 mW, 6 mW, 7 mW, 8 mW, 9 mW, 10 mW, 20 mW, 30 mW, 40 mW, 50 mW, 60 mW, 70 mW, 80 mW, 90 mW, 100 mW, 200 mW, 300 mW, 400 mW, 500 mW, 600 mW, 700 mW, 800 mW, 900 mW, 1 Watt (W), 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1,000 W, or more. The RF energy may comprise an average power of at most about 1,000 W, 900 W, 800 W, 700 W, 600 W, 500 W, 400 W, 300 W, 200 W, 100 W, 90 W, 80 W, 70 W, 60 W, 50 W, 40 W, 30 W, 20 W, 10 W, 9 W, 8 W, 7 W, 6 W, 5 W, 4 W, 3 W, 2 W, 1 W, 900 mW, 800 mW, 700 mW, 600 mW, 500 mW, 400 mW, 300 mW, 200 mW, 100 mW, 90 mW, 80 mW, 70 mW, 60 mW, 50 mW, 40 mW, 30 mW, 20 mW, 10 mW, 9 mW, 8 mW, 7 mW, 6 mW, 5 mW, 4 mW, 3 mW, 2 mW, 1 mW, 900 μW, 800 μW, 700 μW, 600 μW, 500 μW, 400 μW, 300 μW, 200 μW, 100 μW, 90 μW, 80 μW, 70 μW, 60 μW, 50 μW, 40 μW, 30 μW, 20 μW, 10 μW, 9 μW, 8 μW, 7 μW, 6 μW, 5 μW, 4 μW, 3 μW, 2 μW, 1 μW, or less. The RF energy may comprise an average power that is within a range defined by any two of the preceding values.

The electromagnetic delivery unit may comprise one or more light sources, such as any light source described herein. For instance, the electromagnetic delivery unit may comprise light source 221. Although depicted as comprising a single light source in FIG. 4, the electromagnetic delivery unit may comprise any number of light sources, such as at least about 1, 2, 3, 4, 5, 6, 7, 8, 9, 10, or more light sources or at most about 10, 9, 8, 7, 6, 5, 4, 3, 2, or 1 light sources.

The light sources may be configured to direct light to one or more OMs configured to selectively apply the electromagnetic energy to one or more atoms of the plurality of atoms. For instance, the electromagnetic delivery unit may comprise OM 222. Although depicted as comprising a single OM in FIG. 4, the electromagnetic delivery unit may comprise any number of OMs, such as at least about 1, 2, 3, 4, 5, 6, 7, 8, 9, 10, or more OMs or at most about 10, 9, 8, 7, 6, 5, 4, 3, 2, or 1 OMs. The OMs may comprise one or more SLMs, AODs, or AOMs. The OMs may comprise one or more DMDs. The OMs may comprise one or more liquid crystal devices, such as one or more LCoS devices.

The electromagnetic delivery unit may comprise one or more electromagnetic energy artificial intelligence (AI) units configured to perform one or more AI operations to selectively apply the electromagnetic energy to the atoms. For instance, the electromagnetic delivery unit may comprise AI unit 223. Although depicted as comprising a single AI unit in FIG. 4, the electromagnetic delivery unit may comprise any number of AI units, such as at least about 1, 2, 3, 4, 5, 6, 7, 8, 9, 10, or more AI units or at most about 10, 9, 8, 7, 6, 5, 4, 3, 2, or 1 AI units. The AI operations may comprise any machine learning (ML) or reinforcement learning (RL) operations described herein.

The electromagnetic delivery unit may be configured to apply one or more single-qubit operations (such as one or more single-qubit gate operations) on the qubits described herein. The electromagnetic delivery unit may be configured to apply one or more two-qubit operations (such as one or more two-qubit gate operations) on the two-qubit units described herein. Each single-qubit or two-qubit operation may comprise a duration of at least about 10 nanoseconds (ns), 20 ns, 30 ns, 40 ns, 50 ns, 60 ns, 70 ns, 80 ns, 90 ns, 100 ns, 200 ns, 300 ns, 400 ns, 500 ns, 600 ns, 700 ns, 800 ns, 900 ns, 1 microsecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, or more. Each single-qubit or two-qubit operation may comprise a duration of at most about 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, or less. Each single-qubit or two-qubit operation may comprise a duration that is within a range defined by any two of the preceding values. The single-qubit or two-qubit operations may be applied with a repetition frequency of at least 1 kilohertz (kHz), 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1,000 kHz, or more. The single-qubit or two-qubit operations may be applied with a repetition frequency of at most 1,000 kHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, or less. The single-qubit or two-qubit operations may be applied with a repetition frequency that is within a range defined by any two of the preceding values.

The electromagnetic delivery unit may be configured to apply one or more single-qubit operations by inducing one or more Raman transitions between a first qubit state and a second qubit state described herein. The Raman transitions may be detuned from a ³P₀ or ³P₁ line described herein. For instance, the Raman transitions may be detuned by at least about 1 kHz, 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 MHz, 2 MHz, 3 MHz, 4 MHz, 5 MHz, 6 MHz, 7 MHz, 8 MHz, 9 MHz, 10 MHz, 20 MHz, 30 MHz, 40 MHz, 50 MHz, 60 MHz, 70 MHz, 80 MHz, 90 MHz, 100 MHz, 200 MHz, 300 MHz, 400 MHz, 500 MHz, 600 MHz, 700 MHz, 800 MHz, 900 MHz, 1 GHz, or more. The Raman transitions may be detuned by at most about 1 GHz, 900 MHz, 800 MHz, 700 MHz, 600 MHz, 500 MHz, 400 MHz, 300 MHz, 200 MHz, 100 MHz, 90 MHz, 80 MHz, 70 MHz, 60 MHz, 50 MHz, 40 MHz, 30 MHz, 20 MHz, 10 MHz, 9 MHz, 8 MHz, 7 MHz, 6 MHz, 5 MHz, 4 MHz, 3 MHz, 2 MHz, 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, or less. The Raman transitions may be detuned by a value that is within a range defined by any two of the preceding values.

Raman transitions may be induced on individually selected atoms using one or more spatial light modulators (SLMs) or acousto-optic deflectors (AODs) to impart a deflection angle and/or a frequency shift to a light beam based on an applied radio-frequency (RF) signal. The SLM or AOD may be combined with an optical conditioning system that images the SLM or AOD active region onto the back focal plane of a microscope objective. The microscope objective may perform a spatial Fourier transform on the optical field at the position of the SLM or AOD. As such, angle (which may be proportional to RF frequency) may be converted into position. For example, applying a comb of radio frequencies to an AOD may generate a linear array of spots at a focal plane of the objective, with each spot having a finite extent determined by the characteristics of the optical conditioning system (such as the point spread function of the optical conditioning system).

To perform a Raman transition on a single atom with a single SLM or AOD, a pair of frequencies may be applied to the SLM or AOD simultaneously. The two frequencies of the pair may have a frequency difference that matches or nearly matches the splitting energy between the first and second qubit states. For instance, the frequency difference may differ from the splitting energy by at most about 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, 900 Hz, 800 Hz, 700 Hz, 600 Hz, 500 Hz, 400 Hz, 300 Hz, 200 Hz, 100 Hz, 90 Hz, 80 Hz, 70 Hz, 60 Hz, 50 Hz, 40 Hz, 30 Hz, 20 Hz, 10 Hz, 9 Hz, 8 Hz, 7 Hz, 6 Hz, 5 Hz, 4 Hz, 3 Hz, 2 Hz, 1 Hz, or less. The frequency difference may differ from the splitting energy by at least about 1 Hz, 2 Hz, 3 Hz, 4 Hz, 5 Hz, 6 Hz, 7 Hz, 8 Hz, 9 Hz, 10 Hz, 20 Hz, 30 Hz, 40 Hz, 50 Hz, 60 Hz, 70 Hz, 80 Hz, 90 Hz, 100 Hz, 200 Hz, 300 Hz, 400 Hz, 500 Hz, 600 Hz, 700 Hz, 800 Hz, 900 Hz, 1 kHz, 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 MHz, or more. The frequency difference may differ from the splitting energy by about 0 Hz. The frequency difference may differ from the splitting energy by a value that is within a range defined by any two of the preceding values. The optical system may be configured such that the position spacing corresponding to the frequency difference is not resolved and such that light at both of the two frequencies interacts with a single atom.

The electromagnetic delivery units may be configured to provide a beam with a characteristic dimension of at least about 10 nm, 50 nm, 75 nm, 100 nm, 125 nm, 150 nm, 175 nm, 200 nm, 225 nm, 250 nm, 275 nm, 300 nm, 325 nm, 350 nm, 375 nm, 400 nm, 425 nm, 450 nm, 475 nm, 500 nm, 525 nm, 550 nm, 575 nm, 600 nm, 625 nm, 650 nm, 675 nm, 700 nm, 725 nm, 750 nm, 775 nm, 800 nm, 825 nm, 850 nm, 875 nm, 900 nm, 925 nm, 950 nm, 975 nm, 1 micrometer (μm), 1.5 μm, 2 μm, 2.5 μm 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, or more. The electromagnetic delivery units may be configured to provide a beam with a characteristic dimension of at most about 10 μm, 9.5 μm, 9 μm, 8.5 μm, 8 μm, 7.5 μm, 7 μm, 6.5 μm, 6 μm, 5.5 μm, 5 μm, 4.5 μm, 4 μm, 3.5 μm, 3 μm, 2.5 μm, 2 μm, 1.5 μm, 1 μm, 975 nm, 950 nm, 925 nm, 900 nm, 875 nm, 850 nm, 825 nm, 800 nm, 775 nm, 750 nm, 725 nm, 700 nm, 675 nm, 650 nm, 625 nm, 600 nm, 575 nm, 550 nm, 525 nm, 500 nm, 475 nm, 450 nm, 425 nm, 400 nm, 375 nm, 350 nm, 325 nm, 300 nm, 275 nm, 250 nm, 225 nm, 200 nm, 175 nm, 150 nm, 125 nm, 100 nm, 75 nm, 25 nm, 10 nm, or less. The electromagnetic delivery units may be configured to provide a beam with a characteristic dimension as defined by any two of the proceeding values. For example, the beam can have a characteristic dimension of about 1.5 micrometers to about 2.5 micrometers. Examples of characteristic dimensions include, but are not limited to, a Gaussian beam waist, the full width at half maximum (FWHM) of the beam size, the beam diameter, the 1/e² width, the D4σ width, the D86 width, and the like. For example, the beam may have a Gaussian beam waist of at least about 1.5 micrometers.

The characteristic dimension of the beam may be bounded at the low end by the size of the atomic wavepacket of an optical trapping site. For example, the beam can be formed such that the intensity variation of the beam over the trapping site is sufficiently small as to be substantially homogeneous over the trapping site. In this example, the beam homogeneity can improve the fidelity of a qubit in the trapping site. The characteristic dimension of the beam may be bounded at the high end by the spacing between trapping sites. For example, a beam can be formed such that it is small enough that the effect of the beam on a neighboring trapping site/atom is negligible. In this example, the effect may be negligible if the effect can be minimized by techniques such as, for example, composite pulse engineering. The characteristic dimension may be different from a maximum achievable resolution of the system. For example, a system can have a maximum resolution of 700 nm, but the system may be operated at 1.5 micrometers. In this example, the value of the characteristic dimension may be selected to optimize the performance of the system in view of the considerations described elsewhere herein. The characteristic dimension may be invariant for different maximally achievable resolutions. For example, a system with a maximum resolution of 500 nm and a system with a maximum resolution of 2 micrometers may both be configured to operate at a characteristic dimension of 2 micrometers. In this example, 2 micrometers may be the optimal resolution based on the size of the trapping sites.

### Example of Integrated Optical Trapping Units and Electromagnetic Delivery Units

The optical trapping units and electromagnetic delivery units described herein may be integrated into a single optical system. A microscope objective may be used to deliver electromagnetic radiation generated by an electromagnetic delivery unit described herein and to deliver light for trapping atoms generated by an optical trapping unit described herein. Alternatively or in addition, different objectives may be used to deliver electromagnetic radiation generated by an electromagnetic delivery unit and to deliver light from trapping atoms generated by an optical trapping unit.

A single SLM or AOD may allow the implementation of qubit operations (such as any single-qubit or two-qubit operations described herein) on a linear array of atoms. Alternatively or in addition, two separate SLMs or AODs may be configured to each handle light with orthogonal polarizations. The light with orthogonal polarizations may be overlapped before the microscope objective. In such a scheme, each photon used in a two-photon transition described herein may be passed to the objective by a separate SLM or AOD, which may allow for increased polarization control. Qubit operations may be performed on a two-dimensional arrangement of atoms by bringing light from a first SLM or AOD into a second SLM or AOD that is oriented substantially orthogonally to the first SLM or AOD via an optical relay. Alternatively or in addition, qubit operations may be performed on a two-dimensional arrangement of atoms by using a one-dimensional array of SLMs or AODs.

The stability of qubit gate fidelity may be improved by maintaining overlap of light from the various light sources described herein (such as light sources associated with the optical trapping units or electromagnetic delivery units described herein). Such overlap may be maintained by an optical subsystem that measures the direction of light emitted by the various light sources, allowing closed-loop control of the direction of light emission. The optical subsystem may comprise a pickoff mirror located before the microscope objective. The pickoff mirror may be configured to direct a small amount of light to a lens, which may focus a collimated beam and convert angular deviation into position deviation. A position-sensitive optical detector, such as a lateral-effect position sensor or quadrant photodiode, may convert the position deviation into an electronic signal and information about the deviation may be fed into a compensation optic, such as an active mirror.

The stability of qubit gate manipulation may be improved by controlling the intensity of light from the various light sources described herein (such as light sources associated with the optical trapping units or electromagnetic delivery units described herein). Such intensity control may be maintained by an optical subsystem that measures the intensity of light emitted by the various light sources, allowing closed-loop control of the intensity. Each light source may be coupled to an intensity actuator, such as an intensity servo control. The actuator may comprise an acousto-optic modulator (AOM) or electro-optic modulator (EOM). The intensity may be measured using an optical detector, such as a photodiode or any other optical detector described herein. Information about the intensity may be integrated into a feedback loop to stabilize the intensity.

### Example of State Preparation Units

FIG. 5 shows an example of a state preparation unit 250. The state preparation unit may be configured to prepare a state of the plurality of atoms, as described herein. The state preparation unit may be coupled to the optical trapping unit and may direct atoms that have been prepared by the state preparation unit to the optical trapping unit. The state preparation unit may be configured to cool the plurality of atoms. The state preparation unit may be configured to cool the plurality of atoms prior to trapping the plurality of atoms at the plurality of optical trapping sites.

The state preparation unit may comprise one or more Zeeman slowers. For instance, the state preparation unit may comprise a Zeeman slower 251. Although depicted as comprising a single Zeeman slower in FIG. 5, the state preparation may comprise any number of Zeeman slowers, such as at least about 1, 2, 3, 4, 5, 6, 7, 8, 9, 10, or more Zeeman slowers or at most about 10, 9, 8, 7, 6, 5, 4, 3, 2, or 1 Zeeman slowers. The Zeeman slowers may be configured to cool one or more atoms of the plurality of atoms from a first velocity or distribution of velocities (such an emission velocity from an of an atom source, room temperature, liquid nitrogen temperature, or any other temperature) to a second velocity that is lower than the first velocity or distribution of velocities.

The first velocity or distribution of velocities may be associated with a temperature of at least about 50 Kelvin (K), 60 K, 70 K, 80 K, 90 K, 100 K, 200 K, 300 K, 400 K, 500 K, 600 K, 700 K, 800 K, 900 K, 1,000 K, or more. The first velocity or distribution of velocities may be associated with a temperature of at most about 1,000 K, 900 K, 800 K, 700 K, 600 K, 500 K, 400 K, 300 K, 200 K, 100 K, 90 K, 80 K, 70 K, 60 K, 50 K, or less. The first velocity or distribution of velocities may be associated with a temperature that is within a range defined by any two of the preceding values. The second velocity may be at least about 1 meter per second (m/s), 2 m/s, 3 m/s, 4 m/s, 5 m/s, 6 m/s, 7 m/s, 8 m/s, 9 m/s, 10 m/s, or more. The second velocity may be at most about 10 m/s, 9 m/s, 8 m/s, 7 m/s, 6 m/s, 5 m/s, 4 m/s, 3 m/s, 2 m/s, 1 m/s, or less. The second velocity may be within a range defined by any two of the preceding values. The Zeeman slowers may comprise 1D Zeeman slowers.

The state preparation unit may comprise a first magneto-optical trap (MOT) 252. The first MOT may be configured to cool the atoms to a first temperature. The first temperature may be at most about 10 millikelvin (mK), 9 mK, 8 mK, 7 mK, 6 mK, 5 mK, 4 mK, 3 mK, 2 mK, 1 mK, 0.9 mK, 0.8 mK, 0.7 mK, 0.6 mK, 0.5 mK, 0.4 mK, 0.3 mK, 0.2 mK, 0.1 mK, or less. The first temperature may be at least about 0.1 mK, 0.2 mK, 0.3 mK, 0.4 mK, 0.5 mK, 0.6 mK, 0.7 mK, 0.8 mK, 0.9 mK, 1 mK, 2 mK, 3 mK, 4 mK, 5 mK, 6 mK, 7 mK, 8 mK, 9 mK, 10 mK, or more. The first temperature may be within a range defined by any two of the preceding values. The first MOT may comprise a 1D, 2D, or 3D MOT.

The first MOT may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise a second MOT 253. The second MOT may be configured to cool the atoms from the first temperature to a second temperature that is lower than the first temperature. The second temperature may be at most about 100 microkelvin (μK), 90 μK, 80 μK, 70 μK, 60 μK, 50 μK, 40 μK, 30 μK, 20 μK, 10 μK, 9 μK, 8 μK, 7 μK, 6 μK, 5 μK, 4 μK, 3 μK, 2 μK, 1 μK, 900 nanokelvin (nK), 800 nK, 700 nK, 600 nK, 500 nK, 400 nK, 300 nK, 200 nK, 100 nK, or less. The second temperature may be at least about 100 nK, 200 nK, 300 nK, 400 nK, 500 nK, 600 nK, 700 nK, 800 nK, 900 nK, 1 μK, 2 μK, 3 μK, 4 μK, 5 μK, 6 μK, 7 μK, 8 μK, 9 μK, 10 μK, 20 μK, 30 μK, 40 μK, 50 μK, 60 μK, 70 μK, 80 μK, 90 μK, 100 μK, or more. The second temperature may be within a range defined by any two of the preceding values. The second MOT may comprise a 1D, 2D, or 3D MOT.

The second MOT may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

Although depicted as comprising two MOTs in FIG. 5, the state preparation unit may comprise any number of MOTs, such as at least about 1, 2, 3, 4, 5, 6, 7, 8, 9, 10, or more MOTs or at most about 10, 9, 8, 7, 6, 5, 4, 3, 2, or 1 MOTs.

The state preparation unit may comprise one or more sideband cooling units or Sisyphus cooling units (such as a sideband cooling unit described in www.arxiv.org/abs/1810.06626 or a Sisyphus cooling unit described in www.arxiv.org/abs/1811.06014, each of which is incorporated herein by reference in its entirety for all purposes). For instance, the state preparation unit may comprise sideband cooling unit or Sisyphus cooling unit 254. Although depicted as comprising a single sideband cooling unit or Sisyphus cooling unit in FIG. 5, the state preparation may comprise any number of sideband cooling units or Sisyphus cooling units, such as at least about 1, 2, 3, 4, 5, 6, 7, 8, 9, 10, or more sideband cooling units or Sisyphus cooling units, or at most about 10, 9, 8, 7, 6, 5, 4, 3, 2, or 1 sideband cooling units or Sisyphus cooling units. The sideband cooling units or Sisyphus cooling units may be configured to use sideband cooling to cool the atoms from the second temperature to a third temperature that is lower than the second temperature. The third temperature may be at most about 10 μK, 9 μK, 8 μK, 7 μK, 6 μK, 5 μK, 4 μK, 3 μK, 2 μK, 1 μK, 900 nK, 800 nK, 700 nK, 600 nK, 500 nK, 400 nK, 300 nK, 200 nK, 100 nK, 90 nK, 80 nK, 70 nK, 60 nK, 50 nK, 40 nK, 30 nK, 20 nK, 10 nK, or less. The third temperature may be at most about 10 nK, 20 nK, 30 nK, 40 nK, 50 nK, 60 nK, 70 nK, 80 nK, 90 nK, 100 nK, 200 nK, 300 nK, 400 nK, 500 nK, 600 nK, 700 nK, 800 nK, 900 nK, 1 μK, 2 μK, 3 μK, 4 μK, 5 μK, 6 μK, 7 μK, 8 μK, 9 μK, 10 μK, or more. The third temperature may be within a range defined by any two of the preceding values.

The sideband cooling units or Sisyphus cooling units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise one or more optical pumping units. For instance, the state preparation unit may comprise optical pumping unit 255. Although depicted as comprising a single optical pumping unit in FIG. 5, the state preparation may comprise any number of optical pumping units, such as at least about 1, 2, 3, 4, 5, 6, 7, 8, 9, 10, or more optical pumping units, or at most about 10, 9, 8, 7, 6, 5, 4, 3, 2, or 1 optical pumping units. The optical pumping units may be configured to emit light to optically pump the atoms from an equilibrium distribution of atomic states to a non-equilibrium atomic state. For instance, the optical pumping units may be configured to emit light to optically pump the atoms from an equilibrium distribution of atomic states to a single pure atomic state. The optical pumping units may be configured to emit light to optically pump the atoms to a ground atomic state or to any other atomic state. The optical pumping units may be configured to optically pump the atoms between any two atomic states. The optical pumping units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise one or more coherent driving units. For instance, the state preparation unit may comprise coherent driving unit 256. Although depicted as comprising a coherent driving unit in FIG. 5, the state preparation may comprise any number of coherent driving units, such as at least about 1, 2, 3, 4, 5, 6, 7, 8, 9, 10, or more coherent driving units or at most about 10, 9, 8, 7, 6, 5, 4, 3, 2, or 1 coherent driving units. The coherent driving units may be configured to coherently drive the atoms from the non-equilibrium state to the first or second atomic states described herein. Thus, the atoms may be optically pumped to an atomic state that is convenient to access (for instance, based on availability of light sources that emit particular wavelengths or based on other factors) and then coherently driven to atomic states described herein that are useful for performing quantum computations. The coherent driving units may be configured to induce a single photon transition between the non-equilibrium state and the first or second atomic state. The coherent driving units may be configured to induce a two-photon transition between the non-equilibrium state and the first or second atomic state. The two-photon transition may be induced using light from two light sources described herein (such as two lasers described herein).

The coherent driving units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The coherent driving units may be configured to induce an RF transition between the non-equilibrium state and the first or second atomic state. The coherent driving units may comprise one or more electromagnetic radiation sources configured to emit electromagnetic radiation configured to induce the RF transition. For instance, the coherent driving units may comprise one or more RF sources (such as any RF source described herein) configured to emit RF radiation. The RF radiation may comprise one or more wavelengths of at least about 10 centimeters (cm), 20 cm, 30 cm, 40 cm, 50 cm, 60 cm, 70 cm, 80 cm, 90 cm, 1 meter (m), 2 m, 3 m, 4 m, 5 m, 6 m, 7 m, 8 m, 9 m, 10 m, or more. The RF radiation may comprise one or more wavelengths of at most about 10 m, 9 m, 8 m, 7 m, 6 m, 5 m, 4 m, 3 m, 2 m, 1 m, 90 cm, 80 cm, 70 cm, 60 cm, 50 cm, 40 cm, 30 cm, 20 cm, 10 cm, or less. The RF radiation may comprise one or more wavelengths that are within a range defined by any two of the preceding values. Alternatively or in addition, the coherent driving units may comprise one or more light sources (such as any light sources described herein) configured to induce a two-photon transition corresponding to the RF transition.

### Example of Controllers

The optical trapping units, electromagnetic delivery units, entanglement units, readout optical units, vacuum units, imaging units, spatial configuration AI units, spatial arrangement AI units, atom rearrangement units, state preparation units, sideband cooling units, optical pumping units, coherent driving units, electromagnetic energy AI units, atom reservoirs, atom movement units, or Rydberg excitation units may include one or more circuits or controllers (such as one or more electronic circuits or controllers) that is connected (for instance, by one or more electronic connections) to the optical trapping units, electromagnetic delivery units, entanglement units, readout optical units, vacuum units, imaging units, spatial configuration AI units, spatial arrangement AI units, atom rearrangement units, state preparation units, sideband cooling units, optical pumping units, coherent driving units, electromagnetic energy AI units, atom reservoirs, atom movement units, or Rydberg excitation units. The circuits or controllers may be configured to control the optical trapping units, electromagnetic delivery units, entanglement units, readout optical units, vacuum units, imaging units, spatial configuration AI units, spatial arrangement AI units, atom rearrangement units, state preparation units, sideband cooling units, optical pumping units, coherent driving units, electromagnetic energy AI units, atom reservoirs, atom movement units, or Rydberg excitation units.

### Example of Non-Classical Computers

In an aspect, the present disclosure provides a non-classical computer comprising: a plurality of qubits comprising greater than 60 atoms, each atom trapped within an optical trapping site of a plurality of spatially distinct optical trapping sites, wherein the plurality of qubits comprise at least a first qubit state and a second qubit state, wherein the first qubit state comprises a first atomic state and the second qubit state comprises a second atomic state; one or more electromagnetic delivery units configured to apply electromagnetic energy to one or more qubits of the plurality of qubits, thereby imparting a non-classical operation to the one or more qubits, which non-classical operation includes a superposition between at least the first qubit state and the second qubit state; one or more entanglement units configured to quantum mechanically entangle at least a subset of the plurality of qubits in the superposition with at least another qubit of the plurality of qubits; and one or more readout optical units configured to perform one or more measurements of the one or more qubits, thereby obtaining a non-classical computation.

In an aspect, the present disclosure provides a non-classical computer comprising a plurality of qubits comprising greater than 60 atoms each trapped within an optical trapping site of a plurality of spatially distinct optical trapping sites.

### Example of Methods for Performing a Non-Classical Computation

In an aspect, the present disclosure provides a method for performing a non-classical computation, comprising: (a) generating a plurality of spatially distinct optical trapping sites, the plurality of optical trapping sites configured to trap a plurality of atoms, the plurality of atoms comprising greater than 60 atoms; (b) applying electromagnetic energy to one or more atoms of the plurality of atoms, thereby inducing the one or more atoms to adopt one or more superposition states of a first atomic state and at least a second atomic state that is different from the first atomic state; (c) quantum mechanically entangling at least a subset of the one or more atoms in the one or more superposition states with at least another atom of the plurality of atoms; and (d) performing one or more optical measurements of the one or more superposition state to obtain the non-classical computation.

FIG. 6 shows a flowchart for an example of a first method 600 for performing a non-classical computation.

In a first operation 610, the method 600 may comprise generating a plurality of spatially distinct optical trapping sites. The plurality of optical trapping sites may be configured to trap a plurality of atoms. The plurality of atoms may comprise greater than 60 atoms. The optical trapping sites may comprise any optical trapping sites described herein. The atoms may comprise any atoms described herein.

In a second operation 620, the method 600 may comprise applying electromagnetic energy to one or more atoms of the plurality of atoms, thereby inducing the one or more atoms to adopt one or more superposition states of a first atomic state and at least a second atomic state that is different from the first atomic state. The electromagnetic energy may comprise any electromagnetic energy described herein. The first atomic state may comprise any first atomic state described herein. The second atomic state may comprise any second atomic state described herein.

In a third operation 630, the method 600 may comprise quantum mechanically entangling at least a subset of the one or more atoms in the one or more superposition states with at least another atom of the plurality of atoms. The atoms may be quantum mechanically entangled in any manner described herein (for instance, as described herein with respect to FIG. 2).

In a fourth operation 640, the method 600 may comprise performing one or more optical measurements of the one or more superposition state to obtain the non-classical computation. The optical measurements may comprise any optical measurements described herein.

In an aspect, the present disclosure provides a method for performing a non-classical computation, comprising: (a) providing a plurality of qubits comprising greater than 60 atoms, each atom trapped within an optical trapping site of a plurality of spatially distinct optical trapping sites, wherein the plurality of qubits comprise at least a first qubit state and a second qubit state, wherein the first qubit state comprises a first atomic state and the second qubit state comprises a second atomic state; (b) applying electromagnetic energy to one or more qubits of the plurality of qubits, thereby imparting a non-classical operation to the one or more qubits, which non-classical operation includes a superposition between at least the first qubit state and the second qubit state; (c) quantum mechanically entangling at least a subset of the plurality of qubits in the superposition with at least another qubit of the plurality of qubits; and (d) performing one or more optical measurements of the one or more qubits, thereby obtaining said the-classical computation.

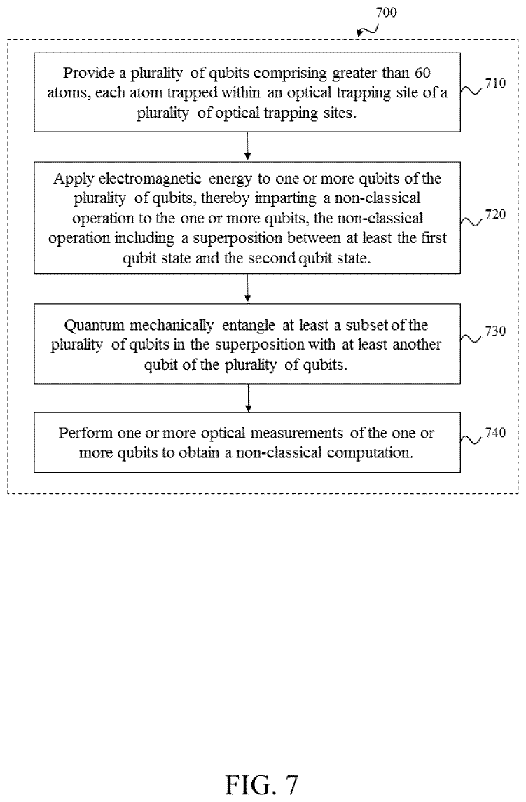

FIG. 7 shows a flowchart for an example of a second method 700 for performing a non-classical computation.

In a first operation 710, the method 700 may comprise providing a plurality of qubits comprising greater than 60 atoms, each atom trapped within an optical trapping site of a plurality of spatially distinct optical trapping sites, wherein the plurality of qubits comprise at least a first qubit state and a second qubit state, wherein the first qubit state comprises a first atomic state and the second qubit state comprises a second atomic state. The optical trapping sites may comprise any optical trapping sites described herein. The qubits may comprise any qubits described herein. The atoms may comprise any atoms described herein. The first qubit state may comprise any first qubit state described herein. The second qubit state may comprise any second qubit state described herein. The first atomic state may comprise any first atomic state described herein. The second atomic state may comprise any second atomic state described herein.

In a second operation 720, the method 700 may comprise applying electromagnetic energy to one or more qubits of the plurality of qubits, thereby imparting a non-classical operation to the one or more qubits, which non-classical operation includes a superposition between at least the first qubit state and the second qubit state. The electromagnetic energy may comprise any electromagnetic energy described herein.

In a third operation 730, the method 700 may comprise quantum mechanically entangling at least a subset of the plurality of qubits in the superposition with at least another qubit of the plurality of qubits. The qubits may be quantum mechanically entangled in any manner described herein (for instance, as described herein with respect to FIG. 2).

In a fourth operation 740, the method 700 may comprise performing one or more optical measurements of the one or more qubits, thereby obtaining the non-classical computation. The optical measurements may comprise any optical measurements described herein.

In an aspect, the present disclosure provides a method for performing a non-classical computation, comprising: (a) providing a plurality of qubits comprising greater than 60 atoms each trapped within an optical trapping site of a plurality of spatially distinct optical trapping sites, and (b) using at least a subset of the plurality of qubits to perform the non-classical computation.

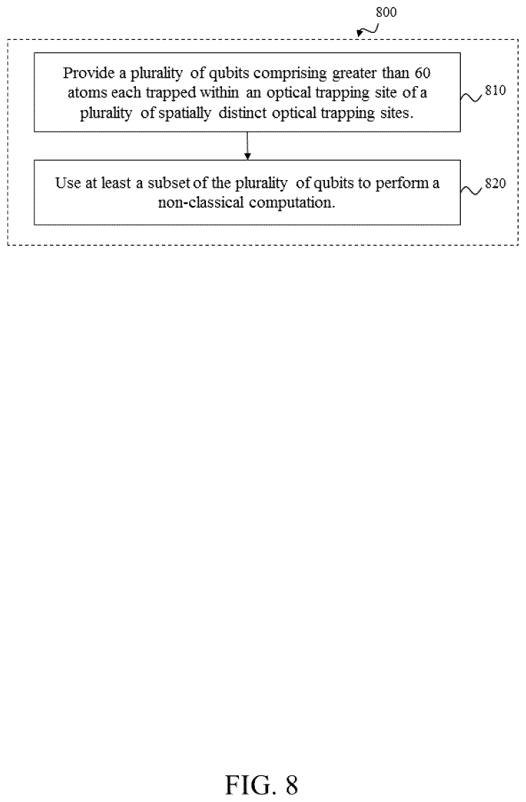

FIG. 8 shows a flowchart for an example of a third method 800 for performing a non-classical computation.

In a first operation 810, the method 800 may comprise providing a plurality of qubits comprising greater than 60 atoms each trapped within an optical trapping site of a plurality of spatially distinct optical trapping sites. The qubits may comprise any qubits described herein. The atoms may comprise any atoms described herein. The optical trapping sites may comprise any optical trapping sites described herein.

In a second operation 820, the method 800 may comprise using at least a subset of the plurality of qubits to perform a non-classical computation.

### Example of Parallel Addressing of Multi-Qubit Units

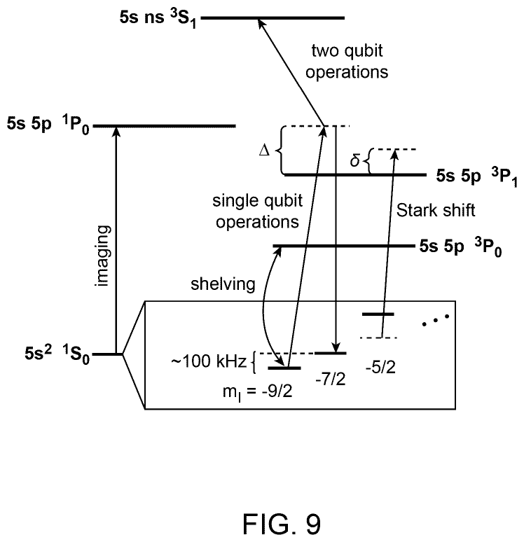

Direct excitation of strontium-87 from the ground state to Rydberg levels would require a laser with a wavelength of approximately 218 nm. Alternatively, the Rydberg excitation operation can be performed using two-photon excitation combining 689 nm and 319 nm light, each detuned from the intermediate ³P₁ state. The approximately 7 kHz width of the ³P₁ state provides an effective balance between the two-photon effective Rabi rate and scattering via spontaneous decay from the ³P₁. FIG. 9 shows an energy level structure for single-qubit and multi-qubit operations in strontium-87.

The optical system for single-qubit operations is also designed to work well for multi-qubit gates. One of the single-qubit beams is used as one leg of the two-photon excitation scheme that drives transitions to the Rydberg electronic manifold. To satisfy the spatially-dependent frequency and phase matching condition, AODs are also used for the UV light. Importantly, the optical systems are matched so that the frequency shift of the UV light from one site to another is identical to that of the 689 nm light. The consequence of this constraint is that the performance of state-of-the-art UV AODs dictate the accessible field of view (FOV) for multi-qubit operations. Further, because one of the single-qubit beams is being used for multi-qubit operations (and the two single-qubit beams are matched), the FOV for single-qubit operations will be the same. A figure of merit for UV AODs is the product of the active aperture and the RF bandwidth of the device. For a fixed beam size in the back focal plane of the objective, increasing either of these quantities results in a larger scan angle of the beams, and thus a larger FOV in the plane of the qubit array. An FOV of approximately 100 μm×100 μm was achieved, which is sufficient to address an array of approximately 1,000 atoms with a trapping site spacing of 3 μm.

### Example of Computer Systems

FIG. 1 shows a computer system 101 that is programmed or otherwise configured to operate any method or system described herein (such as system or method for performing a non-classical computation or of addressing qubits for non-classical computing, described herein). The computer system 101 can regulate various aspects of the present disclosure. The computer system 101 can be an electronic device of a user or a computer system that is remotely located with respect to the electronic device. The electronic device can be a mobile electronic device.

The computer system 101 includes a central processing unit (CPU, also “processor” and “computer processor” herein) 105, which can be a single core or multi core processor, or a plurality of processors for parallel processing. The computer system 101 also includes memory or memory location 110 (e.g., random-access memory, read-only memory, flash memory), electronic storage unit 115 (e.g., hard disk), communication interface 120 (e.g., network adapter) for communicating with one or more other systems, and peripheral devices 125, such as cache, other memory, data storage and/or electronic display adapters. The memory 110, storage unit 115, interface 120 and peripheral devices 125 are in communication with the CPU 105 through a communication bus (solid lines), such as a motherboard. The storage unit 115 can be a data storage unit (or data repository) for storing data. The computer system 101 can be operatively coupled to a computer network (“network”) 130 with the aid of the communication interface 120. The network 130 can be the Internet, an internet and/or extranet, or an intranet and/or extranet that is in communication with the Internet. The network 130 in some cases is a telecommunication and/or data network. The network 130 can include one or more computer servers, which can enable distributed computing, such as cloud computing. The network 130, in some cases with the aid of the computer system 101, can implement a peer-to-peer network, which may enable devices coupled to the computer system 101 to behave as a client or a server.

The CPU 105 can execute a sequence of machine-readable instructions, which can be embodied in a program or software. The instructions may be stored in a memory location, such as the memory 110. The instructions can be directed to the CPU 105, which can subsequently program or otherwise configure the CPU 105 to implement methods of the present disclosure. Examples of operations performed by the CPU 105 can include fetch, decode, execute, and writeback.

The CPU 105 can be part of a circuit, such as an integrated circuit. One or more other components of the system 101 can be included in the circuit. In some cases, the circuit is an application specific integrated circuit (ASIC).

The storage unit 115 can store files, such as drivers, libraries and saved programs. The storage unit 115 can store user data, e.g., user preferences and user programs. The computer system 101 in some cases can include one or more additional data storage units that are external to the computer system 101, such as located on a remote server that is in communication with the computer system 101 through an intranet or the Internet.

The computer system 101 can communicate with one or more remote computer systems through the network 130. For instance, the computer system 101 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 101 via the network 130.

Methods as described herein can be implemented by way of machine (e.g., computer processor) executable code stored on an electronic storage location of the computer system 101, such as, for example, on the memory 110 or electronic storage unit 115. The machine executable or machine-readable code can be provided in the form of software. During use, the code can be executed by the processor 105. In some cases, the code can be retrieved from the storage unit 115 and stored on the memory 110 for ready access by the processor 105. In some situations, the electronic storage unit 115 can be precluded, and machine-executable instructions are stored on memory 110.

The code can be pre-compiled and configured for use with a machine having a processor adapted to execute the code or can be compiled during runtime. The code can be supplied in a programming language that can be selected to enable the code to execute in a pre-compiled or as-compiled fashion.

Aspects of the systems and methods provided herein, such as the computer system 101, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 101 can include or be in communication with an electronic display 135 that comprises a user interface (UI) 140. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 105. The algorithm can, for example, implement methods for performing a non-classical computation described herein.

### Certain Definitions and Additional Considerations

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” “less than or equal to,” or “at most” precedes the first numerical value in a series of two or more numerical values, the term “no more than,” “less than,” “less than or equal to,” or “at most” applies to each of the numerical values in that series of numerical values. For example, less than or equal to 3, 2, or 1 is equivalent to less than or equal to 3, less than or equal to 2, or less than or equal to 1.

Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

As used herein, like characters refer to like elements.

As used herein, the terms “non-classical computation,” “non-classical procedure,” “non-classical operation,” any “non-classical computer” generally refer to any method or system for performing computational procedures outside of the paradigm of classical computing. A non-classical computation, non-classical procedure, non-classical operation, or non-classical computer may comprise a quantum computation, quantum procedure, quantum operation, or quantum computer.

As used herein, the terms “quantum computation,” “quantum procedure,” “quantum operation,” and “quantum computer” generally refer to any method or system for performing computations using quantum mechanical operations (such as unitary transformations or completely positive trace-preserving (CPTP) maps on quantum channels) on a Hilbert space represented by a quantum device. As such, quantum and classical (or digital) computation may be similar in the following aspect: both computations may comprise sequences of instructions performed on input information to then provide an output. Various paradigms of quantum computation may break the quantum operations down into sequences of basic quantum operations that affect a subset of qubits of the quantum device simultaneously. The quantum operations may be selected based on, for instance, their locality or their ease of physical implementation. A quantum procedure or computation may then consist of a sequence of such instructions that in various applications may represent different quantum evolutions on the quantum device. For example, procedures to compute or simulate quantum chemistry may represent the quantum states and the annihilation and creation operators of electron spin-orbitals by using qubits (such as two-level quantum systems) and a universal quantum gate set (such as the Hadamard, controlled-not (CNOT), and rotations) through the so-called Jordan-Wigner transformation or Bravyi-Kitaev transformation.

Additional examples of quantum procedures or computations may include procedures for optimization such as quantum approximate optimization algorithm (QAOA) or quantum minimum finding. QAOA may comprise performing rotations of single qubits and entangling gates of multiple qubits. In quantum adiabatic computation, the instructions may carry stochastic or non-stochastic paths of evolution of an initial quantum system to a final one.

Quantum-inspired procedures may include simulated annealing, parallel tempering, master equation solver, Monte Carlo procedures and the like. Quantum-classical or hybrid algorithms or procedures may comprise such procedures as variational quantum eigensolver (VQE) and the variational and adiabatically navigated quantum eigensolver (VanQver).

A quantum computer may comprise one or more adiabatic quantum computers, quantum gate arrays, one-way quantum computers, topological quantum computers, quantum Turing machines, quantum annealers, Ising solvers, or gate models of quantum computing.

As used herein, the term “adiabatic” refers to any process performed on a quantum mechanical system in which the parameters of the Hamiltonian are changed slowly in comparison to the natural timescale of evolution of the system.

As used herein, the term “non-adiabatic” refers to any process performed quantum mechanical system in which the parameters of the Hamiltonian are changed quickly in comparison to the natural timescale of evolution of the system or on a similar timescale as the natural timescale of evolution of the system.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

1.-49. (canceled)

50. A method of addressing qubits for non-classical computing, comprising:
(a) trapping a plurality of qubits in an array of spatially distinct optical trapping sites, wherein said plurality of qubits comprises a first subset of said plurality of qubits and a second subset of said plurality of qubits, and wherein said first subset and said second subset comprises a target qubit; and
(b) selectively applying a rotation operation to said target qubit and an identity operation to each other qubit in said first subset and said second subset at least in part by exposing (i) said first subset to a first light beam along a first axis and (ii) said second subset to a second light beam along a second axis that is at an angle to said first axis.

51. The method of claim 50, further comprising:
(c) selectively applying a second rotation operation to a second target qubit and an identity operation to each other qubit in a third subset of said plurality of qubits and a fourth subset of said plurality of qubits at least in part by exposing (i) said third subset to a third light beam along a third axis that is parallel or skew to said first axis and (ii) said fourth subset to a fourth light beam along a fourth axis that is parallel or skew to said second axis, wherein said third subset and said fourth subset comprise said second target qubit.

52. The method of claim 51, wherein a first grouping of qubits and a second grouping of qubits are, with exception for said target qubit and said second target qubit, mutually exclusive with respect to one another, and wherein: (i) said first grouping of qubits comprises said first subset and said third subset and (ii) said second grouping of qubits comprises said second subset and said fourth subset.

53. The method of claim 51, wherein said rotation operation is the same as said second rotation operation.

54. The method of claim 51, wherein said rotation operation is different than said second rotation operation.

55. The method of claim 50, wherein said angle is about 90°, and wherein:
(i) said first light beam is configured to apply operations of
$${R}_{x} ( \frac{θ}{2} ) and {R}_{x} ( - \frac{θ}{2} )$$
to said first subset; and
(ii) said second light beam is configured to apply operations of R_{y}(π) and R_{y}(−π) to said second subset.

56. The method of claim 55, wherein said rotation operation applied to said target qubit is a rotation of θ about an x-axis, wherein said first axis corresponds to said x-axis and said second axis corresponds to a y-axis.

57. The method of claim 50, wherein:
(i) said first light beam is configured to apply operations of [A] and [A⁻¹] to said first subset; and
(ii) said second light beam is configured to apply operations of [B] and [B⁻¹] to said second subset
wherein operations [A⁻¹] and [B⁻¹] are applied prior to operations [A] and [B].

58. The method of claim 57, wherein said rotation operation applied to said target qubit is a rotation of θ about an x-axis, wherein said first axis corresponds to said x-axis and said second axis corresponds to a y-axis.

59. The method of claim 50, wherein (b) further comprises:
(c) exposing a third subset of said plurality of qubits to a third light beam along a third axis, wherein:
(i) said third subset comprises said target qubit,
(ii) said third light beam is configured to selectively apply a rotation operation to said target qubit and an identity operation to each other qubit in said first subset and said second subset, and
(iii) said first subset, said second subset, and said third subset are, with exception for said target qubit, mutually exclusive with respect to one another.

60. The method of claim 50, wherein said target qubit is a plurality of qubits.

61. The method of claim 50, wherein said first light beam and said second light beam comprise a beam size configured to select a single target atom.

62. The method of claim 50, wherein said first light beam comprises a pair of optical pulses, and wherein said second light beam comprises a second pair of optical pulses.

63. The method of claim 50, wherein said first light beam is at a first wavelength and said second light beam is at a second wavelength, and wherein said first wavelength is about the same as said second wavelength.

64. The method of claim 50, wherein said first light beam is configured to apply a first operation and a second operation and said second light beam is configured to apply a third operation and a fourth operation.

65. The method of claim 64, wherein said first operation is an inverse of said second operation and said third operation is an inverse of said fourth operation.

66. The method of claim 65, wherein (b) comprises:
(i) with said first light beam, performing said first operation on said first subset and performing said second operation on said second subset; and
(ii) with said second light beam, performing said third operation on said first subset and performing said fourth operation on said second subset.

67. The method of claim 50, wherein said plurality of qubits comprises neutral atoms.

68. The method of claim 67, wherein said neutral atoms comprise a Group II element or a Group II-like element.

69. The method of claim 67, wherein said neutral atoms comprise ytterbium.

70. The method of claim 50, further comprising: performing a non-classical computation based at least in part on selectively applying said rotation operation to said target qubit at (b).
